(19) United States
(12) Patent Application Publication
(10) Pub. No.: US 2009/0104721 A1
(43) Pub. Date: Apr. 23, 2009

(54) Deposition Method and Method for Manufacturing Light Emitting Device

(75) Inventors: Yoshiharu Hirakata, Ebina (JP); Shunpei Yamazaki, Tokyo (JP)

Correspondence Address: Cook Alex Ltd., SUITE 2850, 200 WEST ADAMS STREET, CHICAGO, IL, 60606, US

(73) Assignee: Semiconductor Energy Laboratory Co., Ltd.

(21) Appl. No.: 12/254,060

(22) Filed: Oct. 20, 2008

(30) Foreign Application Priority Data
Oct. 23, 2007 (JP) 2007-274900

(51) Int. Cl. H01L 21/00; B05D 5/12

(52) U.S. Cl. 438/29; 427/64; 257/E21.001

(57) ABSTRACT

An object is to provide a deposition method by which a film having a desired shape can be formed with high productivity. Further, a method for manufacturing a light emitting device by which a light emitting device having high definition can be manufactured with high productivity is provided. Specifically, even in the case of using a large-sized substrate, a method for manufacturing a light emitting device having high definition is provided. By using a deposition target substrate and a shadow mask having a smaller area than the deposition target substrate, the deposition target substrate and the shadow mask are aligned with each other, and an evaporation material is deposited on at least part of the deposition target substrate through a plurality of deposition steps. As an evaporation source, a light absorption layer and a supporting substrate having the evaporation material is preferably used.

### BACKGROUND OF THE INVENTION

1. Field of the Invention

The present invention relates to a deposition method and a method for manufacturing a light emitting device.

2. Description of the Related Art

An organic compound can have various structures in comparison with an inorganic compound, and it is possible to synthesize materials having various functions by appropriate molecular design. Because of these advantages, photo electronics and electronics using a functional organic material have been attracting attention in recent years.

As examples of electronic devices using organic compounds as functional organic materials, there are solar cells, light emitting elements, organic transistors, and the like. These devices take advantage of electric properties and optical properties of the organic compound. Among them, in particular, light emitting elements have been making remarkable progress.

It is said that, as for a light emitting mechanism of a light emitting element, an EL layer is sandwiched between a pair of electrodes and voltage is applied to the EL layer, and thus electrons injected from a cathode and holes injected from an anode are recombined in an emission center of the EL layer to form molecular excitons, and the molecular excitons release energy when returning to a ground state; thus, light is emitted. Singlet excitation and triplet excitation are known as excited states, and it is thought that light emission can be obtained through either of these excited states.

An EL layer included in a light emitting element has at least a light emitting layer. In addition, the EL layer can have a stacked-layer structure including a hole injecting layer, a hole transporting layer, an electron transporting layer, an electron injecting layer, and/or the like, in addition to the light emitting layer.

In addition, EL materials for forming EL layers are broadly classified into a low molecular (monomer) material and a high molecular (polymer) material. In general, a low molecular material is often deposited using an evaporation apparatus and a high molecular material is often deposited using an ink-jet method or the like. A conventional evaporation apparatus, in which a substrate is mounted in a substrate holder, has a crucible (or an evaporation boat) containing an EL material, i.e., an evaporation material; a heater for heating the EL material in the crucible; and a shutter for preventing the subliming the EL material from being scattered. Then, the EL material heated by the heater is sublimed and deposited onto the substrate. In order to achieve uniform deposition, a substrate on which a film is formed (hereinafter referred to as a deposition target substrate) needs to be rotated and the distance between the substrate and the crucible needs to be about 1 m even when the substrate has a size of 300 mm×360 mm.

When this method is employed to manufacture a full-color display device using light emitting elements having emission colors of red, green, and blue, a shadow mask is provided between the substrate and an evaporation source so as to be in contact with the substrate, and selective coloring can be achieved through this shadow mask.

However, the shadow mask which is used for manufacturing the full-color display device is extremely thin since it is necessary to precisely manufacture an opening. Therefore, when the shadow mask size is increased in accordance with an increase in a substrate size, there have been problems of bending of the shadow mask, changing of the size of the opening, and the like. Furthermore, since it is difficult to introduce a means for reinforcing the strength of the shadow mask in a region which corresponds to a pixel portion of the shadow mask, in the case of manufacturing a display region having a large area, application of a reinforcing means is also difficult.

Further, miniaturization of each display pixel pitch is increasingly demanded with high definition of a display device (increase in the number of pixels), and the shadow mask tends to be thin. At the same time, there are increasing demands for improvement of productivity and cost reduction.

Therefore, a method for forming an EL layer of a light emitting element by laser thermal transfer without using a shadow mask has been proposed (see reference 1). Reference 1 discloses that a photo-thermal conversion layer and a transfer layer are provided over a donor film, and a part of the transfer layer irradiated with laser light is separated from the photo-thermal conversion layer by change in adhesion between the photo-thermal conversion layer and the transfer layer. By using such a laser transfer layer, a full-color light emitting element is manufactured.

Further, a method in which a specific portion of a transfer layer is transferred by using a transfer substrate including a light absorption layer and the transfer layer and concentrating laser light into the light absorption layer, has been suggested (see reference 2).

Furthermore, a method in which irradiation of laser light is performed so as to form a desired pattern, by applying laser thermal transfer, by using a photo-thermal conversion layer which includes a low reflective layer and a high reflective layer, and a transfer substrate having a transfer layer, has been suggested (see reference 3).

Reference 1: Japanese Published Patent Application No. 2004-200170

Reference 2: Japanese Published Patent Application No. 2002-110350

Reference 3: Japanese Published Patent Application No. 2006-309995

### SUMMARY OF THE INVENTION

However, in the methods shown in Reference 1 to 3, an only region to be transferred is irradiated with laser light; thus, the time required for processing the entire substrate is long and productivity is low.

Moreover, in the transfer substrate in Reference 3, it is necessary that the low reflective layer and the high reflective layer be included in the transfer substrate, time and cost for manufacturing the transfer substrate are required. In a structure shown in FIG. 3 of Reference 3, as also described in paragraph [0041], the low reflective layer and the high reflective layer are disposed with no space therebetween; therefore, highly precise patterning is necessary.

In view of the above problems, it is an object of the present invention to provide a deposition method by which a film having a desired shape can be formed with high productivity.

Furthermore, a method for manufacturing a light emitting device by which a light emitting device having high definition can be manufactured with high productivity.

In the deposition method of the present invention, a deposition target substrate and a shadow mask which has smaller area than the deposition target substrate are used. Then, an evaporation material is deposited on the deposition target substrate through a plurality of steps. Note that the area of the shadow mask means an occupation area obtained by the product of a length and a width of outside dimension of the shadow mask.

Before deposition is performed, the deposition target substrate and the shadow mask are aligned with each other. That is, the deposition target substrate and the shadow mask are aligned with each other, and a step of depositing the evaporation material on at least one part of the deposition target substrate is performed more than once.

When deposition is performed, a planar evaporation source is preferably used. Specifically, by using a supporting substrate provided with an evaporation material (an evaporation donor substrate), even if a distance between the evaporation source and the deposition target substrate is decreased, variation in a film thickness can be controlled, whereby miniaturization of a deposition device can be achieved. Further, in the case of using a supporting substrate provided with an evaporation material, the film thickness can be easily controlled, which is preferable. Furthermore, since the distance between the evaporation source and the deposition target substrate can be short, material use efficiency is high, which is preferable.

Specifically, as an evaporation source, a light absorption layer and a supporting substrate containing an evaporation material are preferably used. By irradiating the supporting substrate with light from a light source unit and making irradiation light absorbed in a light absorption layer provided for the supporting substrate, the evaporation material provided for the supporting substrate is heated, so that at least part of the evaporation material is evaporated, and accordingly, the evaporation material can be deposited on at least part of the surface of the deposition target substrate through an opening of the shadow mask.

In the aforementioned structure, when the shadow mask is moved to correspond to a large-sized deposition target substrate, it is preferable that the light source unit be also moved.

Moreover, in the aforementioned structure, it is preferable that light emitted from the light source unit be infrared light. The use of infrared light enables the light absorption layer to be heated efficiently.

Furthermore, in the aforementioned structure, it is preferable that the light absorption layer have absorptance of 40% or higher with respect to the light emitted from the light source unit.

In the aforementioned structure, it is preferable that the thickness of the light absorption layer be greater than or equal to 200 nm and less than or equal to 600 nm.

In the aforementioned structure, tantalum nitride, titanium, carbon, or the like can be used for the light absorption layer.

Further, in the aforementioned structure, the evaporation material is preferably attached to the supporting substrate by a wet process. Since material use efficiency in a wet process is high, the use of the wet process makes it possible to reduce the cost for performing deposition.

In the aforementioned structure, an organic compound is preferably used for the evaporation material. As for the organic compound, there are a large number of materials, the evaporation temperature of which is lower than that of an inorganic compound. Thus, the organic compound is suitable for a deposition method of the present invention.

The deposition method described above can be preferably used for manufacturing a light emitting device. Accordingly, one aspect of the present invention is a method for manufacturing a light emitting device, which includes the steps of using a deposition target substrate over which a first electrode is formed, forming a layer containing an evaporation material over the first electrode using the above deposition method, and then forming a second electrode.

In the aforementioned structure, an organic compound is preferably used for the evaporation material. As for the organic compound, there are a large number of materials, the evaporation temperature of which is lower than that of an inorganic compound. Thus, the organic compound is suitable for the method for manufacturing a light emitting device of the present invention. For example, a light emitting material and a carrier transporting material can be used.

By application of the present invention, a film having a desired shape can be formed with high productivity. Specifically, a film having a precise shape can be formed with high precision.

By application of the present invention, a high definition light emitting device can be manufactured with high productivity.

### BRIEF DESCRIPTION OF THE DRAWINGS

FIGS. 1A and 1B describe a film deposition process according to the present invention.

FIGS. 2A and 2B describe a film deposition process according to the present invention.

FIG. 3 describes a film deposition process according to the present invention.

FIGS. 4A and 4B describe a film deposition process according to the present invention.

FIGS. 5A and 5B describe a film deposition process according to the present invention.

FIGS. 6A and 6B describe a film deposition process according to the present invention.

FIGS. 7A and 7B show an example of a light emitting element.

FIGS. 8A and 8B show an example of a light emitting element.

FIGS. 9A to 9C show a top view and cross-sectional views of an example of a passive matrix light emitting device.

FIG. 10 shows a perspective view of an example of a passive matrix light emitting device.

FIG. 11 shows a top view of an example of a passive matrix light emitting device.

FIGS. 12A and 12B show a top view and a cross-sectional view of an example of an active matrix light emitting device.

FIGS. 13A to 13E show examples of electronic devices.

FIGS. 14A to 14C show an example of an electronic device.

FIGS. 15A and 15B describe a film deposition process according to the present invention.

### DETAILED DESCRIPTION OF THE INVENTION

### Embodiment Mode

Hereinafter, embodiment modes of the invention are described with reference to the drawings. However, the present invention is not limited to the description given below, and it will be easily appreciated by those skilled in the art that various changes and modifications of the modes and details are possible, unless such changes and modifications depart from the content and the scope of the invention. Thus, the present invention is not interpreted while limiting to the following description of the embodiment modes and embodiment. It is to be noted that like reference numerals are used to designate identical portions in different drawings in the structure of the invention to be described hereinafter.

### Embodiment Mode 1

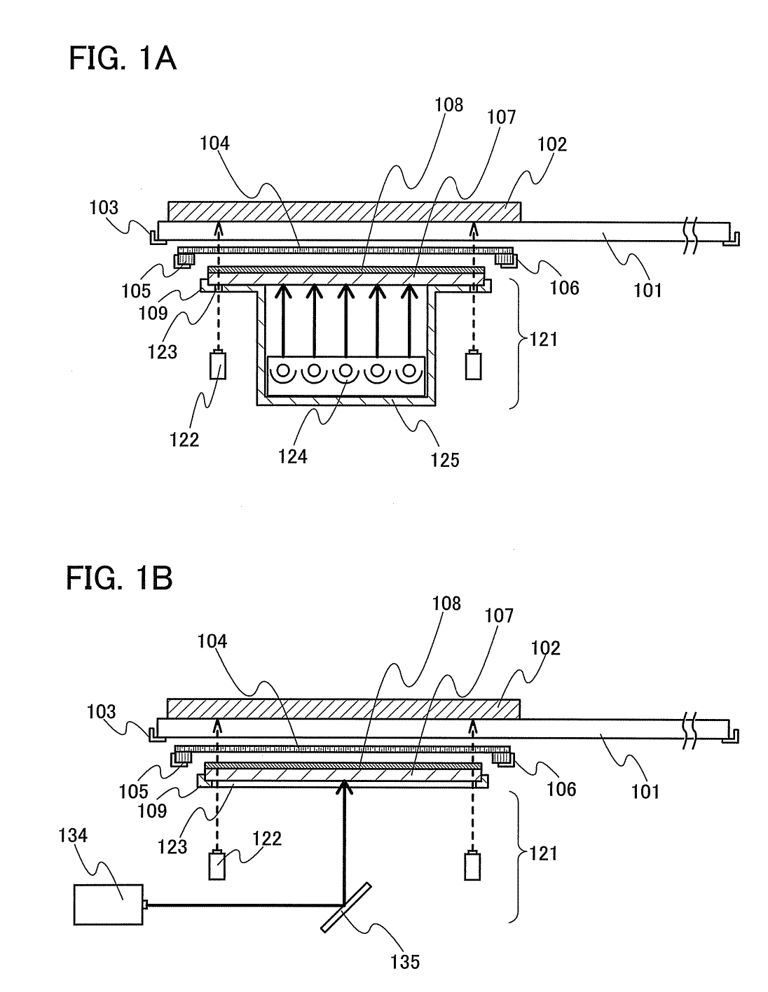

A deposition method and a method for manufacturing a light emitting device according to the present invention will be described with reference to FIGS. 1A and 1B, FIGS. 2A and 2B, FIG. 3, and FIGS. 4A and 4B.

In FIGS. 1A and 1B, a shadow mask 104 is placed between a deposition target substrate 101 and a supporting substrate 107 provided with an evaporation material 108. With an alignment means, the deposition target substrate 101 and the shadow mask are aligned with each other. Then, the evaporation material 108 provided for the supporting substrate 107 is heated by a deposition unit 121, and the vaporized evaporation material is deposited on the deposition target substrate 101 through an opening of the shadow mask 104.

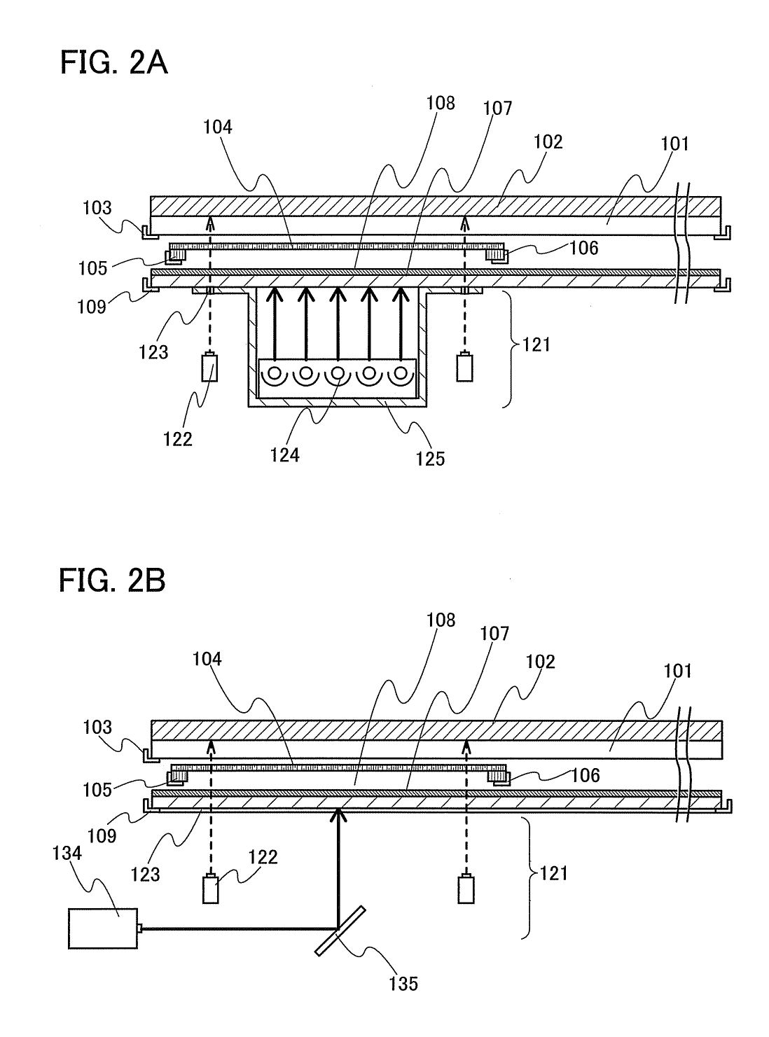

The deposition target substrate 101 is held by a deposition target substrate holding means 103. The deposition target substrate holding means 103 may be part of a deposition target substrate transporting means. In the deposition target substrate 101, it is preferable that a region over which a film is formed keeps a flat surface with the use of a flat plate 102. Therefore, as shown in FIGS. 2A and 2B, the flat plate 102 may be larger than the deposition target substrate 101 so that the entire deposition target substrate 101 keeps a flat surface. Alternatively, as shown in FIGS. 1A and 1B, the flat plate 102 may be smaller than the deposition target substrate 101 so that the flat plate 102 can move. Furthermore, the flat plate 102 may have a magnetic force or a structure having a magnetic force.

Because the shadow mask 104 is extremely thin, it is held by a mask frame 105 so as to have an opening having an appropriate shape. The shadow mask 104 and the mask frame 105 are held by a shadow mask holding means 106. When the shadow mask 104 is made from a metal material, the shadow mask 104 can be held with a magnetic force.

The evaporation material 108 is provided for the supporting substrate 107. The supporting substrate 107 provided with the evaporation material 108 is held by a supporting substrate holding means 109. A structural object other than the evaporation material 108 may be formed over the supporting substrate 107. For example, when light is used as a light source, a light absorption layer may be formed. Further, the size of the supporting substrate 107 may be acceptable as long as it is larger than that corresponding to the opening of the shadow mask 104, or it may have substantially the same size as the deposition target substrate 101 as shown in FIGS. 2A and 2B. When the size of the supporting substrate 107 is substantially the same as that of the deposition target substrate 101, since the evaporation material, the amount of which corresponds to the deposition target substrate, is provided for the supporting substrate 107, frequency of replacing the supporting substrate 107 (supplying the evaporation material) can be reduced.

In FIG. 1A, the supporting substrate holding means 109 has a structure with which a light source holding means 125 holding a lamp 124 that is a light source is combined. There is a window 123 in part of the supporting substrate holding means 109 and the light source holding means 125, and a plurality of cameras 122 to conduct alignment of the deposition target substrate 101 and the shadow mask 104 is provided. By the use of the cameras 122, alignment markers provided for the deposition target substrate 101 and the shadow mask 104 are read, and alignment is conducted.

Then, the deposition target substrate 101 is arranged so as to be in contact with the shadow mask 104. When the flat plate 102 has a magnetic force, and the shadow mask 104 is made from a metal material, the deposition target substrate 101 can be arranged so as to be in contact with the shadow mask 104 by turning the magnetic force of the flat plate 102 on. When a structural object such as an electrode, an insulator, or the like is formed on the surface of the deposition target substrate 101, an outermost surface of the structural object formed on the surface of the deposition target substrate 101 is arranged so as to be in contact with the shadow mask 104. As the distance between the deposition target substrate 101 and the shadow mask 104 is reduced, patterning accuracy of the film to be formed is improved. Thus, it is preferable that the deposition target substrate 101 and the shadow mask 104 be arranged so that distance therebetween is short.

Further, when deposition is performed, it is preferable that the distance between the supporting substrate 107 and the shadow mask 104 be short. By making the distance between the supporting substrate 107 and the shadow mask 104 short, miniaturization of a device can be achieved. Furthermore, patterning accuracy of the film to be formed on the deposition target substrate 101 is improved.

The deposition is performed by heating the evaporation material 108 provided for the supporting substrate 107 by the deposition unit 121 so as to vaporize the evaporation material. In the deposition unit 121 shown in FIG. 1A, a light absorption layer provided for the supporting substrate 107 is irradiated with light from the lamp 124; the light absorption layer is heated; so that the evaporation material provided so as to be in contact with the light absorption layer is heated. Then, the vaporized evaporation material is deposited into a desired pattern on the deposition target substrate 101 through an opening of the shadow mask 104.

It is to be noted that the structure of the deposition unit is not limited to the one shown in FIG. 1A. For example, as shown in FIG. 1B, the structure may be that the supporting substrate 107 is irradiated with a laser 134 as a light source using an optical system 135 such as a mirror through the window 123.

As the light source for light used for irradiating the supporting substrate 107, various light sources such as a lamp, a laser, and the like can be used.

For example, as the light source of laser light, one or more of the following can be used: a gas laser such as an Ar laser, a Kr laser, or an excimer laser; a laser of which medium is single crystal YAG, YVO₄, forsterite (Mg₂SiO₄), YAlO₃, or GdVO₄, or polycrystalline (ceramic) YAG, Y₂O₃, YVO₄, YAlO₃, or GdVO₄, added with one or more of Nd, Yb, Cr, Ti, Ho, Er, Tm, and Ta as a dopant; a glass laser; a ruby laser; an alexandrite laser; a Ti:sapphire laser; a copper vapor laser; or a gold vapor laser. When a solid-state laser whose laser medium is solid is used, there are advantages in that a maintenance-free condition can be maintained for a long time and output is relatively stable.

As the light source other than the laser light, a discharge lamp such as a flash lamp (e.g., a xenon flash lamp or a krypton flash lamp), a xenon lamp, or a metal halide lamp; or an exothermic lamp such as a halogen lamp or a tungsten lamp can be used. With the flash lamp, since a large area can be irradiated with light with extremely high intensity in a short period of time (0.1 to 10 msec) repeatedly, efficient and uniform heating can be performed regardless of the area of the supporting substrate. Further, the flash lamp can control heating of the supporting substrate by change of the interval of emission time. Furthermore, the running cost can be suppressed because of a long life and low power consumption at the time of waiting for light emission of the flash lamp.

It is to be noted that as the light for irradiation, infrared light (a wavelength of 800 nm or more) is preferably used. By using infrared light, the light absorption layer is efficiently heated, and the evaporated material can be efficiently sublimated.

A feature of the invention in a deposition method shown in this embodiment mode is that the light absorption layer is heated with not radiant heat but light from the light source. Further, time for irradiating with light can be relatively short. For example, when a halogen lamp is used as the light source, irradiation of light is maintained at a temperature of 500° C. to 800° C. for 7 to 15 seconds, whereby a material layer can be deposited.

The deposition is preferably performed in a reduced-pressure atmosphere. The reduced-pressure atmosphere can be obtained in such a manner that a deposition chamber is evacuated by an evacuation unit to the degree of vacuum of less than or equal to 5×10⁻³ Pa, preferably 10⁻⁴ to 10⁻⁶ Pa. If the inside of the deposition chamber can be high vacuum, reliability of a light emitting device can be improved; therefore higher vacuum is preferable.

After deposition is performed, in a region of the deposition target substrate 101 where a film is not formed, the shadow mask 104 is placed. At this time, the deposition target substrate 101 may be moved, or the shadow mask 104 and the deposition unit 121 may be moved. When the deposition target substrate 101 is moved, it is not necessary to move the deposition unit 121. Therefore, it is preferable when the deposition unit includes a complex optical system. Furthermore, it can be applied to a deposition apparatus of an in-line type in which the deposition target substrate 101 can be successively formed, which is preferable. Alternatively, when the shadow mask 104 and the deposition unit 121 are moved, it is not necessarily to move the deposition target substrate 101, whereby miniaturization of a device can be achieved. Specifically, it is effective when a large-sized deposition target substrate is used.

The evaporation material corresponding to the opening of the shadow mask 104 is vaporized; therefore, the opening of the shadow mask 104 and the supporting substrate 107 are aligned with each other so that the evaporation material is supplied to the region which corresponds to the opening of the shadow mask 104. Alternatively, the supporting substrate newly provided with an evaporation material is used.

Then, deposition is performed by heating the evaporation material provided for the supporting substrate 107 by the deposition unit 121.

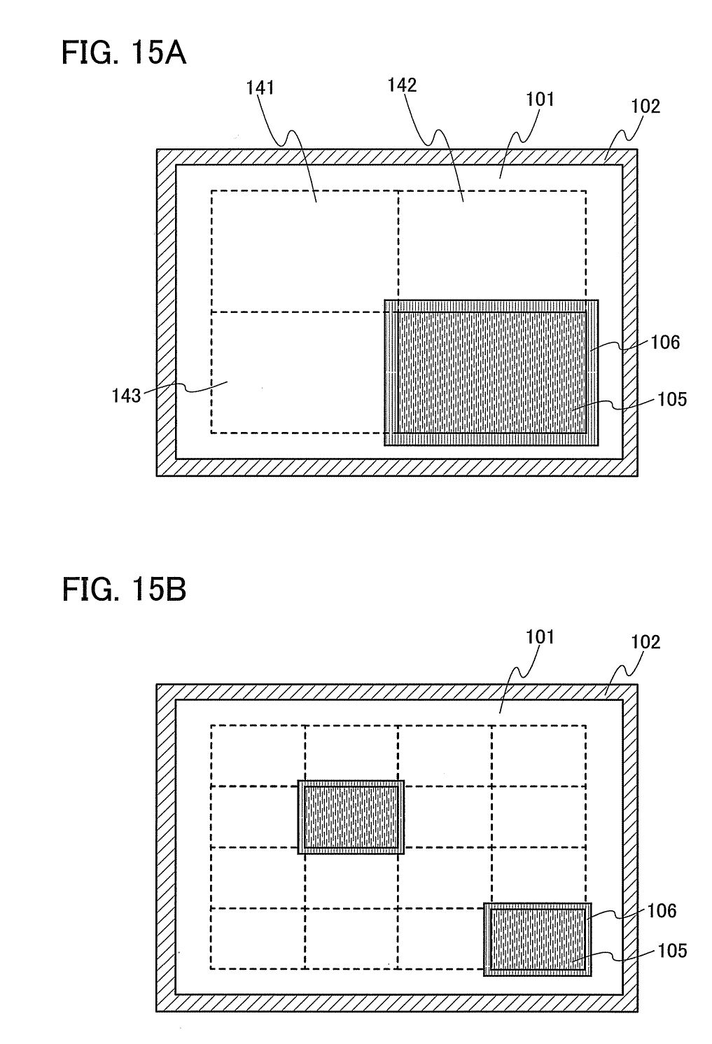

As described above, the deposition is performed more than once, whereby a film can be formed over a large-sized deposition target substrate by using a conventional shadow mask. FIG. 15A shows a case where a film is formed over the deposition target substrate 101 by repeating deposition four times. FIG. 15A shows that a first deposition region 141 is formed through the first deposition, a second deposition region 142 is formed through the second deposition, a third deposition region 143 is formed through the third deposition, and a fourth deposition region is formed through the fourth deposition. The deposition over the deposition target substrate is performed more than once. As shown in FIG. 15B, the deposition target substrate 101 may be divided into more regions to perform the deposition. When the deposition target substrate 101 is divided into more regions to perform the deposition, a plurality of the deposition units is provided, and deposition is preferably performed in accordance with each deposition unit. By using the plurality of deposition units, takt time can be shortened, and higher productivity can be obtained.

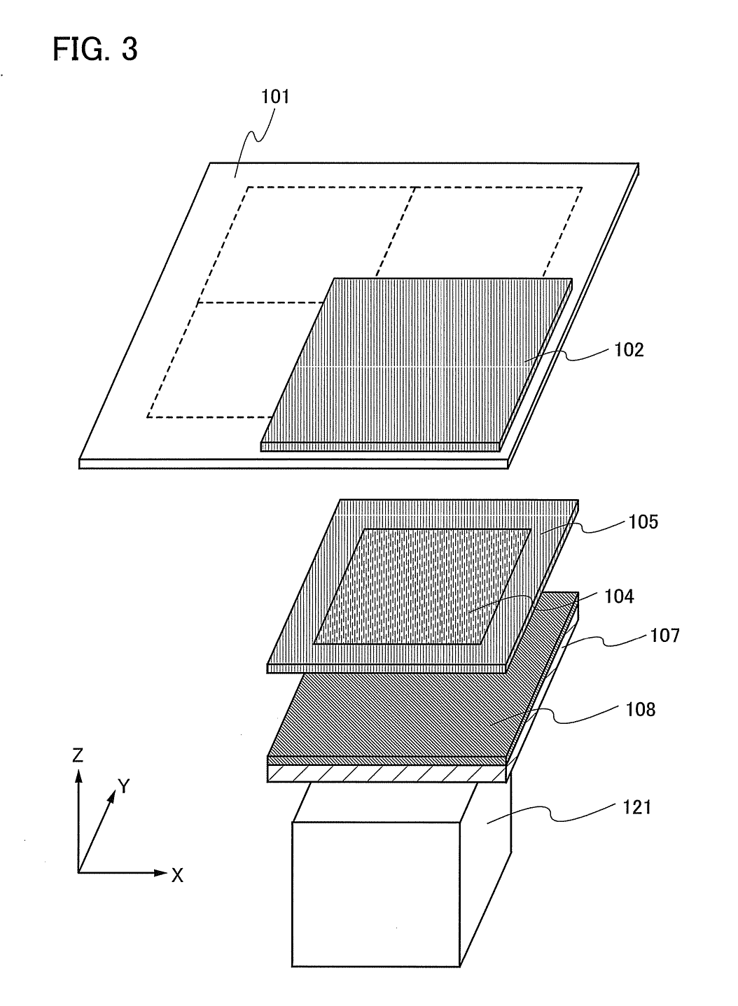

FIG. 3 shows a schematic perspective view of FIG. 1A. As shown in FIG. 3, the deposition target substrate 101 or the shadow mask 104 can be moved in a direction parallel to the deposition target substrate (X direction and Y direction). Further, when the shadow mask 104 is moved, it is also necessary to move the deposition unit 121; therefore, the shadow mask is needed to be moved in a direction parallel to the deposition target substrate (X direction and Y direction). Furthermore, when the flat plate 102 is smaller than the deposition target substrate 101, it is necessary that the flat plate 102 is needed to be moved.

Furthermore, it is necessary to change the distance between the deposition target substrate 101 and the shadow mask 104, and the distance between the shadow mask 104 and the supporting substrate 107; thus, the deposition target substrate 101, the shadow mask 104, and the supporting substrate 107 can be moved in a direction perpendicular to the deposition target substrate (Z direction that is perpendicular to the X-Y plane).

Moreover, the supporting substrate 107 provided with the evaporation material 108 needs to introduce a new supporting substrate from outside so as to supply the evaporation material; therefore, the supporting substrate 107 can be moved in the X direction, Y direction, and Z direction.

In FIGS. 1A and 1B, FIGS. 2A and 2B, and FIG. 3, the shadow mask 104 and the deposition unit 121 are placed below the deposition target substrate 101; however, the shadow mask 104 and the deposition unit 121 may be placed above the deposition target substrate 101. By placing the deposition target substrate 101 on the lower side, the deposition target substrate 101 can be kept flat easily. Further, unlike the case where the evaporation material is held in a crucible or a deposition boat which have been used conventionally, since a planar evaporation source is used as the evaporation source, there is no concern that the evaporation material is spilled out even if it is placed upside down. Furthermore, the deposition target substrate 101 may be placed lengthways. Alternatively, the deposition target substrate 101 may be placed slantingly. Also in the case where the deposition target substrate 101 is placed slantingly, it is easy to keep the deposition target substrate 101 flat using gravity.

As described, by application of the present invention, a film having a desired shape can be formed with high precision. Furthermore, the film can be formed with high productivity. Specifically, in the case of using a large-sized substrate, in a conventional method, a shadow mask is bent, so that it has been difficult to form a film having a desired shape with high precision. By application of the present invention, even in the case of using a large-sized substrate, a film having a desired shape can be formed with high precision. Thus, a large-sized and high definition light emitting device can be manufactured easily.

By application of the present invention, a distance between the deposition target substrate and the supporting substrate provided with the evaporation material can be short, which suppresses adhesion of the evaporation material to a region other than a desired region. Therefore, material use efficiency can be high, and a manufacturing cost required for the deposition can be reduced.

### Embodiment Mode 2

In this embodiment mode, a supporting substrate provided with an evaporation material, and a deposition method will be described in detail.

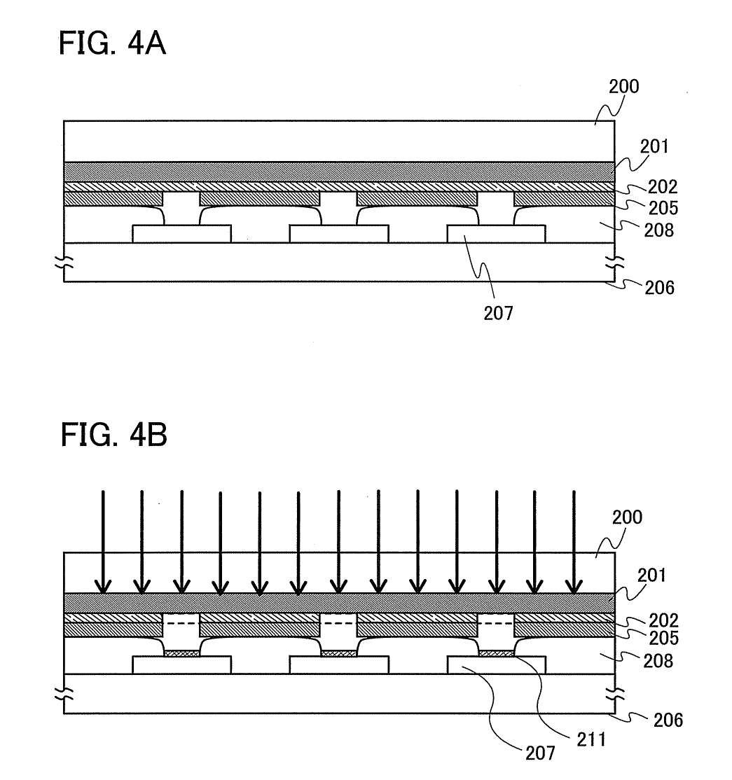

FIG. 4A shows an example of the supporting substrate provided with an evaporation material and the deposition target substrate. In FIG. 4A, a light absorption layer 201 is formed on a surface of a first substrate 200 that is a supporting substrate, which faces a second substrate that is a deposition target substrate. Further, an evaporation material is provided under the light absorption layer 201. In FIG. 4A, a material layer 202 containing the evaporation material is formed.

The first substrate 200 serves as a supporting substrate of the light absorption layer and the material layer, which transmits irradiated light for evaporating the evaporation material in a deposition process. Accordingly, the first substrate 200 is preferably a substrate having high light transmittance. Specifically, when lamp light or laser light is used for evaporating the evaporation material, a substrate which transmits such light is preferably used as the first substrate 200. As the first substrate 200, for example, a glass substrate, a quartz substrate, a plastic substrate including an inorganic material, or the like can be used.

The light absorption layer 201 is a layer which absorbs irradiated light for evaporating the evaporation material in a deposition process. It is preferable that the light absorption layer has lower reflectance, lower transmittance, and higher absorptance with respect to the irradiated light. Specifically, the light absorption layer preferably has reflectance of 60% or lower and absorptance of 40% or higher with respect to the irradiated light. Further the light absorption layer is preferably formed of a material that is excellent in heat resistance. For example, with respect to light having 800 nm wavelength, molybdenum, tantalum nitride, titanium, tungsten, or the like is preferably used. Furthermore, with respect to light having 1300 nm wavelength, tantalum nitride, titanium, or the like is preferably used. As described, a kind of the material suitable for the light absorption layer 201 changes in accordance with a wavelength of the irradiated light for evaporating the evaporation material.

The light absorption layer 201 can be formed by various methods. For example, the light absorption layer 201 can be formed using a target such as molybdenum, tantalum, titanium, or tungsten or a target using an alloy of these metals by a sputtering method. Further, the light absorption layer 201 is not limited to a single layer, and may have a structure in which a plurality of layers is stacked.

The light absorption layer 201 preferable has a film thickness which does not transmit irradiated light. Although it depends on a material to be used, the light absorption layer preferably has a thickness of approximately 100 nm or more. Specifically, by setting the thickness of the light absorption layer 201 to be greater than or equal to 200 nm and less than or equal to 600 nm, the irradiated light is efficiently absorbed, so that heat can be generated.

Note that part of the irradiated light may be transmitted through the light absorption layer 201 as long as the light absorption layer 201 generates heat up to the sublimation temperature of the evaporation material. However, when the part of the irradiated light is transmitted through the light absorption layer 201, it is preferable to use a material which is not decomposed even by irradiated with light.

The material layer 202 contains the evaporation material and is transferred through sublimation. There are various kinds of materials as evaporation materials. The material layer 202 may contain plural kinds of materials. In addition, the material layer 202 may be a single layer or a stack of a plurality of layers. When a plurality of layers each containing an evaporation material is stacked, co-evaporation is possible. Note that it is preferable that a plurality of layers each containing an evaporation material be stacked so as to contain an evaporation material having low decomposition temperature on the first substrate side. Alternatively, it is preferable that a plurality of layers each containing an evaporation material be stacked so as to contain an evaporation material having low evaporation temperature on the first substrate side. Such a structure allows a plurality of layers each containing an evaporation material to be efficiently sublimed and evaporated. Note that the term “evaporation temperature” in this specification refers to a temperature at which a material is sublimed. The term “decomposition temperature” refers to a temperature at which a change is caused by the action of heat in at least a part of a chemical formula that represents a material.

The material layer 202 is formed by various methods. For example, a dry process such as a vacuum evaporation method or a sputtering method can be used. Alternatively, a wet process such as a spin coating method, a spray coating method, an ink-jet method, a dip coating method, a cast method, a dye coating method, a roll coating method, a blade coating method, a bar coating method, a gravure coating method, or a printing method can be used. In order to form the material layer 202 by such a wet process, a desired evaporation material is dissolved or dispersed in a solvent and a solution or a dispersion solution may be controlled. There is no particular limitation on the solvent as long as it can dissolve or disperse an evaporation material and it does not react with the evaporation material. For example, as a solvent, any of the following can be used: halogen solvents such as chloroform, tetrachloromethane, dichloromethane, 1,2-dichloroethane, or chlorobenzene; ketone solvents such as acetone, methyl ethyl ketone, diethyl ketone, n-propyl methyl ketone, or cyclohexanone; aromatic solvents such as benzene, toluene, or xylene; ester solvents such as ethyl acetate, n-propyl acetate, n-butyl acetate, ethyl propionate, γ-butyrolactone, or diethyl carbonate; ether solvents such as tetrahydrofuran or dioxane; amide solvents such as dimethylformamide or dimethylacetamide; dimethyl sulfoxide; hexane; water; or the like. Alternatively, a mixture of plural kinds of the above solvents may be used. The use of a wet process makes it possible to increase material use efficiency and reduce cost required for the deposition.

It is to be noted that thickness and uniformity of a layer 211 containing the evaporation material, which is to be formed in a later step over a second substrate 206 that is a deposition target substrate, depends on the material layer 202 which formed over the first substrate that is a supporting substrate. Therefore, it is important to form the material layer uniformly. Note that the material layer does not necessarily need to be a uniform layer as long as the thickness and uniformity of the layer 211 containing the evaporation material is ensured. For example, the material layer 202 may be formed in a minute island shape or may have unevenness. Further, by controlling the thickness of the material layer 202, the thickness of the layer 211 containing the evaporation material formed over the second substrate 206 that is a deposition target substrate can be controlled easily.

Note that, as an evaporation material, various materials can be used regardless of an organic compound or an inorganic compound. Specifically, because many organic compounds have a lower evaporation temperature than inorganic compounds, organic compounds are easily evaporated by light irradiation and suitable for the deposition method of the present invention. Examples of organic compounds include a light emitting material, a carrier transporting material, and the like used for a light emitting device. Examples of inorganic compounds include a metal oxide, a metal nitride, a metal halide, an elemental metal, and the like used for a carrier transporting layer, a carrier injecting layer, an electrode, and the like of a light emitting device.

Then, as shown in FIG. 4A, a shadow mask 205 is placed so as to be in contact with a surface of the second substrate 206. The second substrate 206 is a deposition target substrate on which a desired layer is deposited through an evaporation process. In the case where a certain layer (e.g., a conductive layer which functions as an electrode, an insulating layer which functions as a partition wall, or the like) is formed on the deposition target substrate, the surface of the shadow mask 205 and the surface of a layer formed on the deposition target substrate are placed so as to be in contact with each other. Note that, in the case where the surface of the layer formed on the deposition target substrate is uneven, the shadow mask 205 and the deposition target substrate are placed so that the shortest distance between the surface of the shadow mask 205 and the deposition target substrate or the outermost surface of the layer formed on the deposition target substrate is 0 mm. By making the distance between the surface of the shadow mask 205 and the surface of the deposition target substrate short, material use efficiency can be improved. Furthermore, patterning accuracy of the layer formed on the deposition target substrate can be improved.

The shadow mask 205 has an opening having a desired pattern. A vaporized evaporation material from the material layer is deposited to the deposition target substrate through the opening. In the case of applying the deposition method according to the present invention to manufacturing a light emitting device, the shadow mask 205 has openings corresponding to each light emitting element.

The first substrate 200 is placed so that a surface of the first substrate 200, on which the light absorption layer 201 and the material layer 202 are formed, and the shadow mask 205 face each other. Then, the first substrate 200 and the shadow mask 205 are brought close to each other so as to face at close range therebetween, specifically, they are brought close to each other so that the distance d between the surface of the material layer provided for the first substrate 200 and the shadow mask 205 becomes greater than or equal to 0 mm and less than or equal to 0.05 mm, preferably greater than or equal to 0 mm and less than or equal to 0.03 mm.

The distance d is defined as the distance between the surface of the material layer 202 formed on the supporting substrate and the surface of the shadow mask 205. However, in the case where the surface of the material layer 202 formed on the supporting substrate is uneven, the distance d is defined as the shortest distance between the surface of the material layer 202 formed over the supporting substrate and the surface of the shadow mask 205.

Although it is preferable that the distance between the first substrate and the shadow mask 205 be short in order to increase material use efficiency, the present invention is not limited to this structure.

In FIGS. 4A and 4B, the second substrate 206 has a first electrode layer 207. The edge portion of the first electrode layer 207 is preferably covered with an insulator 208. In this embodiment mode, the first electrode layer shows an electrode to be an anode or a cathode of the light emitting element.

Subsequently, light irradiation is performed from the side of the first substrate 200 where an evaporation material of the first substrate 200 is not provided. The light absorption layer 201 in a region irradiated with light is heated, and the evaporation material is sublimated using the heat energy. The sublimated evaporation material is attached over the first electrode layer, and the layer 211 containing the evaporation material is formed (FIG. 4B).

As a light source used for the light irradiation, various light sources can be used.

For example, as the light source of laser light, one or more of the following can be used: a gas laser such as an Ar laser, a Kr laser, or an excimer laser; a laser of which medium is single crystal YAG, YVO₄, forsterite (Mg₂SiO₄), YAlO₃, or GdVO₄, or polycrystalline (ceramic) YAG, Y₂O₃, YVO₄, YAlO₃, or GdVO₄, added with one or more of Nd, Yb, Cr, Ti, Ho, Er, Tm, and Ta as a dopant; a glass laser; a ruby laser; an alexandrite laser; a Ti:sapphire laser; a copper vapor laser; or a gold vapor laser. When a solid-state laser whose laser medium is solid is used, there are advantages in that a maintenance-free condition can be maintained for a long time and output is relatively stable.

As the light source other than the laser light, a discharge lamp such as a flash lamp (e.g., a xenon flash lamp or a krypton flash lamp), a xenon lamp, or a metal halide lamp; or an exothermic lamp such as a halogen lamp or a tungsten lamp can be used. With the flash lamp, since a large area can be irradiated with light with extremely high intensity in a short period of time (0.1 to 10 msec) repeatedly, efficient and uniform heating can be performed regardless of the area of the first substrate. Further, the flash lamp can control heating of the first substrate by change of the interval of emission time. Furthermore, the running cost can be suppressed because of a long life and low power consumption at the time of waiting for light emission of the flash lamp.

It is to be noted that as the light for irradiation, infrared light (a wavelength of 800 nm or more) is preferably used. By using infrared light, the light absorption layer 201 is efficiently heated, and the evaporated material can be efficiently sublimated.

A feature of the invention in a deposition method shown in this embodiment mode is that the light absorption layer is heated with not radiant heat but light from the light source. Further, time for irradiating with light can be relatively short. For example, when a halogen lamp is used as the light source, irradiation of light is maintained at a temperature of 500° C. to 800° C. for 7 to 15 seconds, whereby a material layer can be deposited.

The deposition is preferably performed in a reduced-pressure atmosphere. The reduced-pressure atmosphere can be obtained in such a manner that a deposition chamber is evacuated by an evacuation unit to the degree of vacuum of less than or equal to 5×10⁻³ Pa, preferably 10⁻⁴ to 10⁻⁶ Pa. If the inside of the deposition chamber can be high vacuum, reliability of a light emitting device can be improved; therefore higher vacuum is preferable.

It is to be noted that the light absorption layer 201 is formed over the entire surface of the first substrate 200 that is a supporting substrate in FIGS. 4A and 4B; however it is not limited to this structure. For example, the light absorption layer 201 may be provided so as to correspond to the opening of the shadow mask.

This embodiment mode shows a case where the second substrate that is a deposition target substrate is positioned below the first substrate that is a supporting substrate; however, the present invention is not limited to this. The position of the substrate to be placed can be appropriately set.

In the deposition method of the present invention which is applied to the light emitting device, the thickness of the layer containing an evaporation material which is to be formed on the deposition target substrate through an evaporation process can be controlled by control of the thickness of the material layer formed over the supporting substrate. In other words, the material layer formed over the supporting substrate may be evaporated as it is; thus, a film-thickness monitor is not needed. Therefore, a user does not have to adjust the evaporation speed with use of a film-thickness monitor, and the deposition process can be fully automated. Accordingly, productivity can be improved.

In the deposition method of the present invention which is applied to the light emitting device, the evaporation material contained in the material layer can be sublimated uniformly. Therefore, uniformity of the film to be formed is superior. Further, in the case where the material layer contains a plurality of evaporation materials, a layer containing evaporation materials, which contains the same evaporation material as the material layer at approximately the same weight ratio can be deposited on the deposition target substrate. As described above, in the deposition method of the present invention, in the case where deposition is performed using the plurality of evaporation materials whose evaporation temperatures are different from each other, unlike the case of co-evaporation, the evaporation rate of each evaporation material does not need to be controlled. Thus, complicated control of the evaporation rate or the like does not need to be performed, and a desired layer containing different evaporation materials can be deposited easily and precisely.

Application of the present invention also makes it possible to form a flat film without unevenness. Application of the present invention facilitates patterning of a light emitting layer; thus, it also facilitates manufacture of a light emitting device. In addition, a precise pattern can be formed; thus, a high definition light emitting device can be obtained. Furthermore, by application of the present invention, not only a laser but also a lamp heater or the like which is inexpensive but provides a large amount of heat can be used as a light source. Moreover, by use of a lamp heater or the like as a light source, deposition can be performed over a large area at a time; thus, takt time can be shortened. Accordingly, manufacturing cost of a light emitting device can be reduced.

Moreover, the deposition method of the present invention makes it possible to deposit desired evaporation materials on the deposition target substrate without waste of the desired evaporation materials. Thus, the use efficiency of an evaporation material is increased, and reduction in cost can be achieved. In addition, the evaporation materials can be prevented from being attached to the inner wall of the deposition chamber, and maintenance of the deposition apparatus can be easier.

Accordingly, application of the present invention makes it possible to easily deposit a desired layer containing different evaporation materials and to improve productivity in manufacture of a light emitting device using the layer containing different evaporation materials, or the like.

By using the evaporation donor substrate of the present invention, the evaporation material can be deposited with high use efficiency, and cost reduction can be achieved. Further, by using the evaporation donor substrate of the present invention, a film having a desired shape can be formed with high precision.

Specifically, in the case of manufacturing a full-color light emitting display device using light emitting elements having emission colors of red, green, and blue, by application of the deposition method of the present invention, selective coloring of the light emitting layer can be achieved with high precision. Further, takt time can be shortened, whereby a light emitting device can be manufactured with high productivity. Furthermore, by enhancing the use efficiency of an EL material, manufacturing cost can be reduced.

This embodiment mode can be appropriately combined with any of other embodiment modes described in this specification.

### Embodiment Mode 3

In this embodiment mode, a method for manufacturing a full-color display device using a deposition method described in Embodiment Modes 1 and 2 is described.

Although FIGS. 4A and 4B show an example in which deposition is performed on each of the adjacent first electrode layers 207 in one deposition step, light emitting layers which emit light of different colors are formed in different regions in a plurality of deposition steps when a full-color display device is manufactured.

A manufacturing example of a light emitting device that is capable of full color display is described below. In this embodiment mode, an example of a light emitting device using light emitting layers which emit light of three colors is described.

Three supporting substrates provided with evaporation materials shown in FIG. 4A (evaporation donor substrates) are prepared. A plurality of layers each containing different evaporation material is formed over each of the irradiated substrates. Specifically, the first evaporation donor substrate provided with a material layer for a red light emitting layer, the second evaporation donor substrate provided with a material layer for a green light emitting layer, and the third evaporation donor substrate provided with a material layer for a blue light emitting layer are prepared.

In addition, one deposition target substrate provided with first electrode layers is prepared. Note that it is preferable to provide an insulator which covers edge portions of each of the first electrode layers and serves as a partition wall so that the adjacent first electrode layers are not short-circuited. A region which serves as a light emitting region corresponds to part of the first electrode layers, that is, a region which does not overlap with the insulator and is exposed.

Then, the deposition target substrate and the shadow mask are made to overlap with each other and aligned with each other. A marker for alignment provided over the deposition target substrate and a maker for the shadow mask are used for the alignment.

Then, the first evaporation donor substrate is placed so that a surface of the first evaporation donor substrate, over which the material layer of the first evaporation donor substrate is provided, and a shadow mask face each other. Subsequently, light irradiation is performed from the opposite side of the surface of the first evaporation donor substrate whose surface is provided with a material layer of the first evaporation donor substrate. The irradiated light is absorbed in a light absorption layer, so that the light absorption layer generates heat and the material layer for a red light emitting layer, which is in contact with the light absorption layer is sublimated, whereby a first deposition is performed onto the first electrode layers provided over the deposition target substrate through an opening of the shadow mask. After the first deposition, the first evaporation donor substrate is moved away from the deposition target substrate.

Next, the deposition target substrate and the shadow mask are overlapped with each other and aligned with each other. The deposition target substrate and the shadow mask are aligned with each other so that the position of the deposition target substrate and the shadow mask is shifted by one pixel from the position of a film formed at the time of the first deposition.

Then, the second evaporation donor substrate is placed so that a surface of the second evaporation donor substrate, over which the material layer of the second evaporation donor substrate is provided, and a shadow mask face each other. Subsequently, light irradiation is performed from the opposite side of the surface of the second evaporation donor substrate whose surface is provided with a material layer of the second evaporation donor substrate. The irradiated light is absorbed in a light absorption layer, so that the light absorption layer generates heat and the material layer for a green light emitting layer, which is in contact with the light absorption layer, is sublimated, whereby a second deposition is performed onto the first electrode layers provided over the deposition target substrate. After the second deposition, the second evaporation donor substrate is moved away from the deposition target substrate.

Next, the deposition target substrate and the shadow mask are overlapped with each other and aligned with each other. The deposition target substrate and the shadow mask are aligned with each other so that the position of the deposition target substrate and the shadow mask is shifted by two pixels from the position of the film formed at the time of the first deposition.

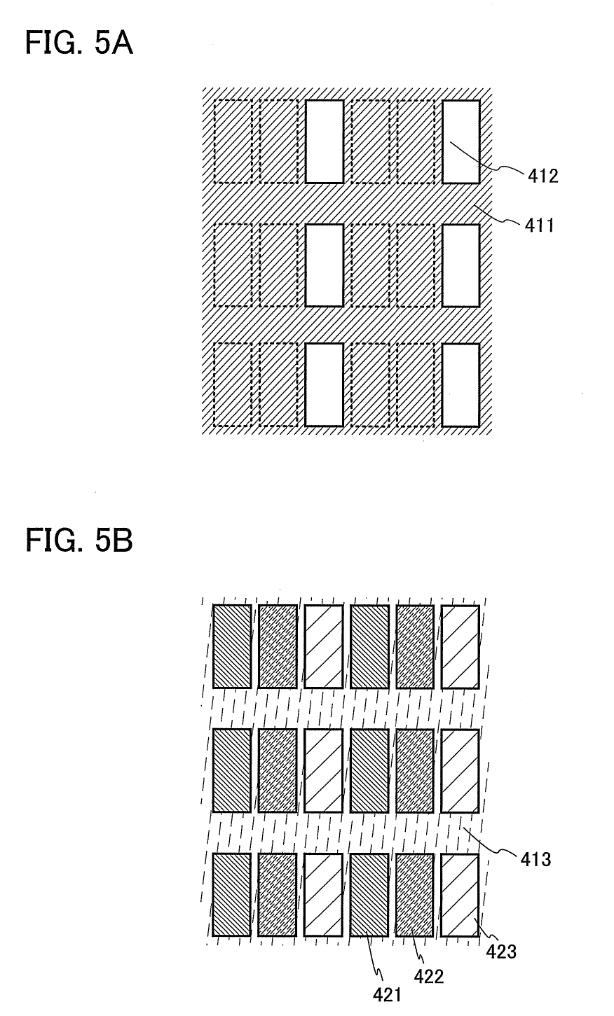

Then, the third evaporation donor substrate is placed so that a surface of the third evaporation donor substrate, over which the material layer of the third evaporation donor substrate is provided, and a shadow mask face each other. Subsequently, light irradiation is performed from the opposite side of the surface of the third evaporation donor substrate whose surface is provided with a material layer of the third evaporation donor substrate, and a third deposition is performed. FIG. 5A is a top view illustrating the state immediately before the third deposition is performed. In FIG. 5A, a shadow mask 411 has openings 412. The material layer and a light absorption layer are formed in a region corresponding to the openings 412 in the third deposition target substrate. Further, the region corresponding to the openings 412 in the deposition target substrate is a region in which the first electrode layers are not covered with an insulator 413 and is exposed. Note that first films 421 (R) which have been formed in the first deposition and second films (G) 422 which have been formed in the second deposition are located under regions indicated by the dotted lines in FIG. 5A.

Through the third deposition, third films (B) 423 are formed. The irradiated light is absorbed in a light absorption layer, so that the light absorption layer generates heat and the material layer for a blue light emitting layer, which is in contact with the light absorption layer is sublimated, whereby the third deposition is performed onto the first electrode layers provided over the deposition target substrate. After the third deposition, the third evaporation donor substrate is moved away from the deposition target substrate.

Accordingly, the first films (R) 421, the second films (G) 422, and the third films (B) 423 are selectively formed at regular intervals (FIG. 5B). Then, second electrode layers are formed over these films, whereby the light emitting elements are formed.

Through the above steps, a full-color display device can be manufactured.

Although the example in which the openings 412 of the shadow mask 411 are rectangular is illustrated in FIGS. 5A and 5B, the present invention is not limited thereto, and stripe openings may be employed. In the case where the stripe openings are employed, although deposition is also performed between light emitting regions which emit color of the same color, a film is formed over the insulator 413, and thus the portion which overlaps with the insulator 413 does not serve as a light emitting region.

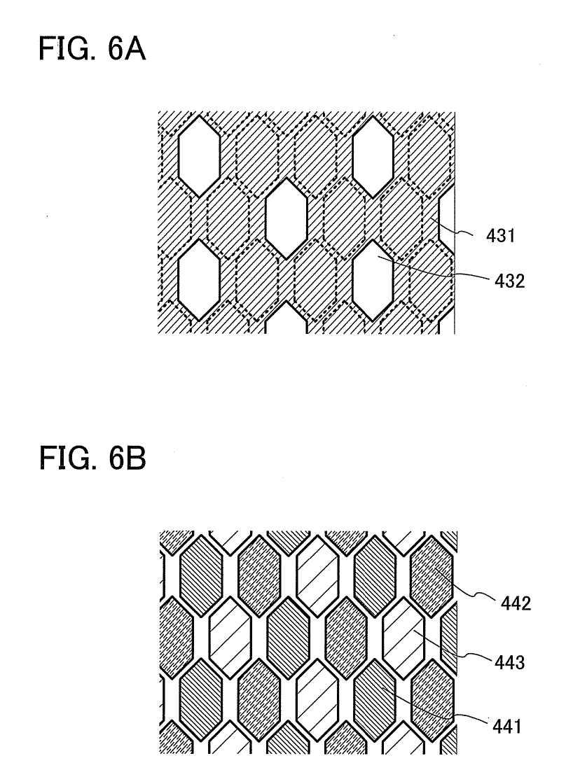

In addition, there is no particular limitation on the alignment of the pixels. The shape of one pixel may be polygonal, for example, hexagonal as shown in FIG. 6B, and a fall-color display device may be realized by placement of first films (R) 441, second films (G) 442, and third films (B) 443. In order to form the pixel having a polygonal shape as shown in FIG. 6B, deposition may be performed using a shadow mask 431 having polygonal openings 432 shown in FIG. 6A.

Application of the present invention makes it possible to easily form a layer containing an evaporation material forming a light emitting element and to manufacture a light emitting device including the light emitting element. Application of the present invention also makes it possible to form a flat film without unevenness. Application of the present invention facilitates patterning of a light emitting layer; takt time can be shortened; thus, productivity of the light emitting device is improved. In addition, a precise pattern can be formed; thus, a high definition light emitting device can be obtained. Specifically, in the case of using a large-sized substrate, in a conventional method, a shadow mask is bent, so that it has been difficult to form a film having a desired shape with high precision. By application of the present invention, even in the case of using a large-sized substrate, a film having a desired shape can be formed with high precision. Thus, a large-sized and high definition light emitting device can be manufactured easily. Furthermore, by application of the present invention, not only a laser but also a lamp heater or the like which is inexpensive but provides a large amount of heat can be used as a light source. Accordingly, manufacturing cost of a light emitting device can be reduced.

In addition, by application of the present invention, less complicated control is needed in the case where a light emitting layer in which a dopant material is dispersed in a host material is formed than in the case where co-evaporation is applied. Moreover, since it is easy to control the additive amount of dopant material, or the like, deposition can be performed easily and precisely, and thus desired emission color can be easily obtained. Furthermore, the use efficiency of an evaporation material can be enhanced, and thus cost reduction can be realized.

This embodiment mode can be appropriately combined with any of other embodiment modes described in this specification.

### Embodiment Mode 4

In this embodiment mode, a method for manufacturing a light emitting element and a light emitting device, to which the present invention is applied, will be described.

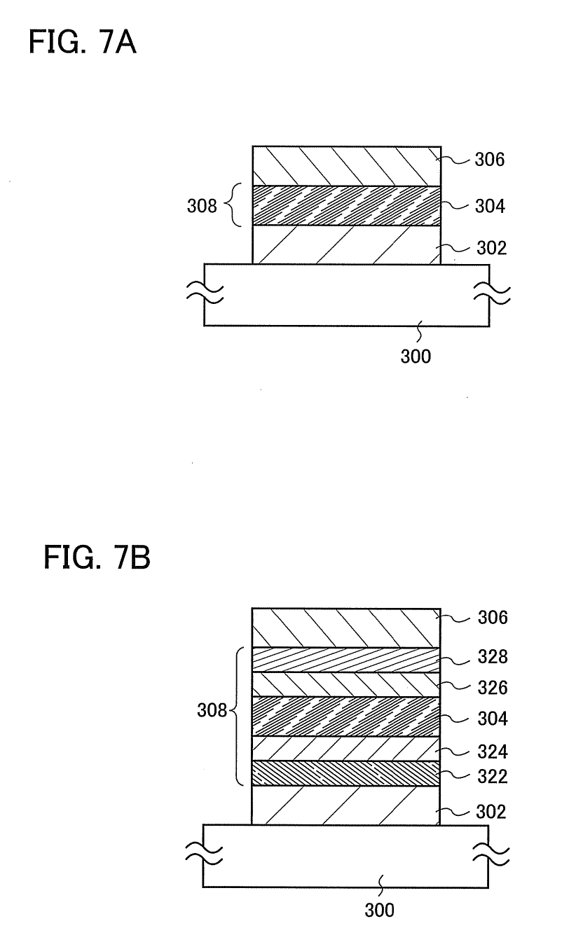

For example, light emitting elements shown in FIGS. 7A and 7B can be manufactured. In the light emitting element shown in FIG. 7A, a first electrode layer 302, an EL layer 308 which functions as a light emitting layer 304, and a second electrode layer 306 are stacked in this order over a substrate 300. One of the first electrode layer 302 and the second electrode layer 306 functions as an anode, and the other functions as a cathode. Holes injected from the anode and electrons injected from the cathode are recombined in the light emitting layer 304, whereby light emission can be obtained. In this embodiment mode, the first electrode layer 302 functions as an anode and the second electrode layer 306 functions as a cathode.

In the light emitting element shown in FIG. 7B, a hole injecting layer, a hole transporting layer, an electron transporting layer, and an electron injecting layer are provided, in addition to the components in the above-described structure shown in FIG. 7A. The hole transporting layer is provided between the anode and the light emitting layer. In addition, the hole injecting layer is provided between the anode and the hole transporting layer. On the other hand, the electron transporting layer is provided between the cathode and the light emitting layer, and the electron injecting layer is provided between the cathode and the electron transporting layer. Note that all of the hole injecting layer, the hole transporting layer, the electron transporting layer, and the electron injecting layer are not necessarily provided, and the layer which is to be provided may be selected as appropriate in accordance with the required function or the like. In FIG. 7B, the first electrode layer 302 which functions as an anode, a hole injecting layer 322, a hole transporting layer 324, the light emitting layer 304, an electron transporting layer 326, an electron injecting layer 328, and the second electrode layer 306 which functions as a cathode are stacked in this order over the substrate 300.

As the substrate 300, a substrate with an insulating surface or an insulating substrate is used. Specifically, any of a variety of glass substrates made of glass used for the electronics industry, such as aluminosilicate glass, aluminoborosilicate glass, or barium borosilicate glass; a quartz substrate; a ceramic substrate; a sapphire substrate; or the like can be used.

As the first electrode layer 302 and the second electrode layer 306, various types of metal, alloys, electrically conductive compounds, mixtures of these can be used. For example, indium tin oxide (ITO), indium tin oxide containing silicon or silicon oxide, indium zinc oxide (IZO), indium oxide containing tungsten oxide and zinc oxide (IWZO), and the like can be given. Although films including such conductive metal oxide are generally formed by sputtering, a sol-gel method or the like may also be applied. For example, indium zinc oxide (IZO) can be formed by a sputtering method using a target in which zinc oxide of 1 to 20 wt % is added to indium oxide. Indium oxide containing tungsten oxide and zinc oxide (IWZO) can be formed by a sputtering method using a target in which 0.5 to 5 wt % of tungsten oxide and 0.1 to 1 wt % of zinc oxide are contained in indium oxide. Besides, gold (Au), platinum (Pt), nickel (Ni), tungsten (W), chromium (Cr), molybdenum (Mo), iron (Fe), cobalt (Co), copper (Cu), palladium (Pd), nitride of a metal material (e.g., titanium nitride), and the like can be given. Alternatively, aluminum (Al), silver (Ag), an alloy containing aluminum (AlSi), or the like can be used. Alternatively, any of the following materials with a low work function can be used: elements which belong to Group 1 or Group 2 of the periodic table, that is, alkali metal such as lithium (Li) and cesium (Cs) and alkaline-earth metal such as magnesium (Mg), calcium (Ca), and strontium (Sr), and alloys thereof (an alloy of aluminum, magnesium, and silver, or an alloy of aluminum and lithium); rare earth metal such as europium (Eu) and ytterbium (Yb), and alloys thereof; and the like. A film made of an alkali metal, an alkaline earth metal, or an alloy of them can be formed by a vacuum evaporation method. Alternatively, a film made of an alloy of alkali metal or alkaline earth metal can be formed by a sputtering method. It is also possible to deposit a silver paste or the like by an ink-jet method or the like. The first electrode layer 302 and the second electrode layer 306 can be formed as a stacked-layer film without being limited to a single-layer film.

Note that in order to extract light emitted from the light emitting layer 304 to the outside, one or both of the first electrode layer 302 and the second electrode layer 306 is/are formed so as to transmit light. For example, one or both of the first electrode layer 302 and the second electrode layer 306 is/are formed using a conductive material having a light-transmitting property, such as indium tin oxide, or formed using silver, aluminum, or the like to have a thickness of several nanometers to several tens of nanometers. Alternatively, one or both of the first electrode layer 302 and the second electrode layer 306 can have a stacked-layer structure including a thin film of a metal such as silver, aluminum, or the like with a small thickness and a thin film of a conductive material having a light-transmitting property, such as ITO. Note that the first electrode layer 302 or the second electrode layer 306 may be formed by any of various methods.

The light emitting layer 304, the hole injecting layer 322, the hole transporting layer 324, the electron transporting layer 326, or the electron injecting layer 328 can be formed by application of the deposition method described in above Embodiment Modes 1 to 3. In addition, the electrode layer can also be formed by application of the deposition method described in above Embodiment Modes 1 to 3.

For example, in the case where the light emitting element shown in FIG. 7A is formed, a light absorption layer and a first layer containing an evaporation material, which serves as an evaporation source for forming a light emitting layer, are formed on a surface of the supporting substrate; and the supporting substrate is disposed close to a deposition target substrate. By light irradiation, the first layer containing the evaporation material which is formed over the supporting substrate is heated and sublimed to form the light emitting layer 304 over the deposition target substrate. Then, the second electrode layer 306 is formed over the light emitting layer 304. The deposition target substrate here is the substrate 300. Note that, over the deposition target substrate, the first electrode layer 302 is formed in advance.

Various kinds of materials can be used for the light emitting layer 304. For example, a fluorescent compound which exhibits fluorescence or a phosphorescent compound which exhibits phosphorescence can be used.

Examples of phosphorescent compounds that can be used for the light emitting layer are given below. Examples of blue light emitting materials include: bis[2-(4′,6′-difluorophenyl)pyridinato-N,C^{2′}]iridium(III) tetralis(1-pyrazolyl)borate (abbr.: FIr6); bis[2-(4′,6′-difluorophenyl)pyridinato-N,C^{2′}]iridium(III) picolinate (abbr.: FIrpic); bis[2-(3′,5′bistrifluoromethylphenyl)pyridinato-N,C^{2′}]iridium(III) picolinate (abbr.: Ir(CF₃ppy)₂(pic)); bis[2-(4′,6′-difluorophenyl)pyridinato-N,C^{2′}]iridium(III) acetylacetonate (abbr.: FIracac); and the like. Examples of green light emitting materials include: tris(2-phenylpyridinato-N,C^{2′})iridium(III) (abbr.: Ir(Ppy)₃); bis(2-phenylpyridinato-N,C^{2′})iridium(III) acetylacetonate (abbr.: Ir(ppy)₂(acac)); bis(1,2-diphenyl-1H-benzimidazolato)iridium(III) acetylacetonate (abbr.: Ir(pbi)₂(acac)); bis(benzo[h]quinolinato)iridium(III) acetylacetonate (abbr.: Ir(bzq)₂(acac)); and the like. Examples of yellow light emitting material include: bis(2,4-diphenyl-1,3-oxazolato-N,C^{2′})iridium(III) acetylacetonate (abbr.: Ir(dpo)₂(acac)); bis[2-(4′-perfluorophenylphenyl)pyridinato]iridium(III) acetylacetonate (abbr.: Ir(p-PF-ph)₂(acac)); bis(2-phenylbenzothiazolato-N,C^{2′})iridium(III) acetylacetonate (abbr.: Ir(bt)₂(acac)); and the like. Examples of orange light emitting materials include: tris(2-phenylquinolinato-N,C²′)iridium(III) (abbr.: Ir(pq)₃); bis(2-phenylquinolinato-N,C^{2′})iridium(III) acetylacetonate (abbr.: Ir(pq)₂(acac)); and the like. Examples of red light emitting materials include organic metal complexes, such as bis[2-(2′-benzo[4,5-a]thienyl)pyridinato-N,C^{3′}]iridium(III) acetylacetonate (abbr.: Ir(btp)₂(acac)), bis(1-phenylisoquinolinato-N,C^{2′})iridium(III) acetylacetonate (abbr.: Ir(piq)₂(acac)), (acetylacetonato)bis[2,3-bis(4-fluorophenyl)quinoxalinato]iridium(III) (abbr.: Ir(Fdpq)₂(acac)), and 2,3,7,8,12,13,17,18-octaethyl-21H,23H-porphyrin platinum(II) (abbr.: PtOEP). In addition, rare-earth metal complexes, such as tris(acetylacetonato)(monophenanthroline)terbium(III) (abbr.: Tb(acac)₃(Phen)), tris(1,3-diphenyl-1,3-propanedionato)(monophenanthroline)europium(III) (abbr.: Eu(DBM)₃(Phen)), and tris[1-(2-thenoyl)-3,3,3-trifluoroacetonato](monophenanthroline)europium(III) (abbr.: Eu(TTA)₃(Phen)), exhibit light emission from rare-earth metal ions (electron transition between different multiplicities); thus, rare-earth metal complexes can be used as phosphorescent compounds.

Examples of fluorescent compounds that can be used for the light emitting layer are given below. Examples of blue light emitting materials include: N,N′-bis[4-(9H-carbazol-9-yl)phenyl]-N,N′-diphenylstilbene-4,4′-diamine (abbr.: YGA2S); 4-(9H-carbazol-9-yl)-4′-(10-phenyl-9-anthryl)triphenylamine (abbr.: YGAPA); and the like. Examples of green light emitting materials include: N-(9,10-diphenyl-2-anthryl)-N,9-diphenyl-9H-carbazol-3-amine (abbr.: 2PCAPA); N-[9,10-bis(1,1′-biphenyl-2-yl)-2-anthryl]-N,9-diphenyl-9H-carbazol-3-amine (abbr.: 2PCABPhA); N-(9,10-diphenyl-2-anthryl)-N,N′,N′-triphenyl-1,4-phenylenediamine (abbr.: 2DPAPA); N-[9,10-bis(1,1′-biphenyl-2-yl)-2-anthryl]-N,N′,N′-triphenyl-1,4-phenylenediamine (abbr.: 2DPABPhA); 9,10-bis(1,1′-biphenyl-2-yl)-N-[4-(9H-carbazol-9-yl)phenyl]-N-phenylanthracen-2-amine (abbr.: 2YGABPhA); N,N,9-triphenylanthracen-9-amine (abbr.: DPhAPhA); and the like. Examples of yellow light emitting materials include: rubrene; 5,12-bis(1,1′-biphenyl-4-yl)-6,11-diphenyltetracene (abbr.: BPT); and the like. Examples of red light emitting materials include: N,N,N′,N′-tetrakis(4-methylphenyl)tetracene-5,11-diamine (abbr.: p-mPhTD); 7,13-diphenyl-N,N,N′,N′-tetrakis(4-methylphenyl)acenaphtho[1,2-a]fluoranthene-3,10-diamine (abbr.: p-mPhAFD); and the like.

The light emitting layer 304 may have a structure in which a substance having a high light emitting property (a dopant material) is dispersed in another substance (a host material), whereby crystallization of the light emitting layer can be suppressed. In addition, concentration quenching which results from high concentration of the substance having a high light emitting property can be suppressed.

As the substance in which the substance having a high light emitting property is dispersed, when the substance having a high light emitting property is a fluorescent compound, a substance having singlet excitation energy (the energy difference between a ground state and a singlet excited state) higher than the fluorescent compound is preferably used. When the substance having a high light emitting property is a phosphorescent compound, a substance having higher triplet excitation energy (the energy difference between a ground state and a triplet excited state) than the phosphorescent compound is preferably used.

Examples of host materials used for the light emitting layer include: 4,4′-bis[N-(1-naphthyl)-N-phenylamino]biphenyl (abbr.: NPB); tris(8-quinolinolato)aluminum(III) (abbr.: Alq); 4,4′-bis[N-(9,9-dimethylfluorene-2-yl)-N-phenylamino]biphenyl (abbr.: DFLDPBi); bis(2-methyl-8-quinolinolato)(4-phenylphenolato)aluminum(III) (abbr.: BAlq); 4,4′-di(9-carbazolyl)biphenyl (abbr.: CBP); 2-tert-butyl-9,10-di(2-naphthyl)anthracene (abbr.: t-BuDNA); 9-[4-(9-carbazolyl)phenyl]-10-phenylanthracene (abbr.: CZPA); and the like.

As the dopant material, any of the above-mentioned phosphorescent compounds and fluorescent compounds can be used.

When the light emitting layer has a structure in which a substance having a high light emitting property (a dopant material) is dispersed in another substance (a host material), a mixed layer of a host material and a guest material is formed as the first layer containing the evaporation material which serves as an evaporation source. Alternatively, the first layer containing the evaporation material which serves as an evaporation source may have a structure in which a layer containing a host material and a layer containing a dopant material are stacked. The light emitting layer 304, when formed using an evaporation source having such a structure, contains a substance in which a light emitting material is dispersed (host material) and a substance having a high light emitting property (dopant material), and has a structure in which the substance having a high light emitting property (dopant material) is dispersed in the substance in which a light emitting material is dispersed (host material). Note that, for the light emitting layer, two or more kinds of host materials and a dopant material may be used, or two or more kinds of dopant materials and a host material may be used. Alternatively, two or more kinds of host materials and two or more kinds of dopant materials may be used.

In addition, in the case where the light emitting element shown in FIG. 7B, in which various functional layers are stacked, is formed, the following procedure may be repeated: a layer containing an evaporation material is formed over a supporting substrate; the supporting substrate is disposed close to a deposition target substrate; the layer containing the evaporation material which is formed over the supporting substrate is heated and sublimed, thereby forming a functional layer over the deposition target substrate. For example, a material layer which serves as an evaporation source for forming a hole injecting layer is formed over a supporting substrate; the supporting substrate is disposed close to a deposition target substrate; and the material layer formed over the supporting substrate is heated and sublimed, thereby forming the hole injecting layer 322 over the deposition target substrate. The deposition target substrate here is the substrate 300 and is provided with the first electrode layer 302 in advance. Successively, a material layer which serves as an evaporation source for forming a hole transporting layer is formed over a supporting substrate; the supporting substrate is disposed close to the deposition target substrate; and the material layer formed over the supporting substrate is heated and sublimed, thereby forming the hole transporting layer 324 over the hole injecting layer 322 over the deposition target substrate. After that, the light emitting layer 304, the electron transporting layer 326, and the electron injecting layer 328 are sequentially stacked in a similar manner, and then the second electrode layer 306 is formed.

The hole injecting layer 322, the hole transporting layer 324, the electron transporting layer 326, or the electron injecting layer 328 may be formed using various EL materials. Each layer may be formed using one kind of material or a composite material of plural kinds of materials. In the case where a layer is formed using a composite material, a material layer containing plural kinds of evaporation materials is formed as described above. Alternatively, a material layer containing an evaporation material is formed by stacking a plurality of layers each containing an evaporation material. In the case where a layer is formed using one kind of material, the deposition method described above in Embodiment Modes 1 to 3 can also be applied. Moreover, each of the hole injecting layer 322, the hole transporting layer 324, the electron transporting layer 326, and the electron injecting layer 328 may have a single-layer structure or a stacked-layer structure. For example, the hole transporting layer 324 may have a stacked-layer structure of a first hole transporting layer and a second hole transporting layer. In addition, the electrode layer can be formed by the deposition method described in Embodiment Modes 1 to 3.

For example, the hole injecting layer 322 can be formed using molybdenum oxide, vanadium oxide, ruthenium oxide, tungsten oxide, manganese oxide, or the like. Alternatively, the hole injecting layer can be formed using a phthalocyanine-based compound such as phthalocyanine (abbr.: H₂Pc) or copper phthalocyanine (abbr.: CuPc), a high molecular compound such as poly(3,4-ethylenedioxythiophene)/poly(styrenesufonate) (PEDOT/PSS), or the like.

As the hole injecting layer 322, a layer which contains a substance having a high hole transporting property and a substance having an electron accepting property can be used. The layer which contains a substance having a high hole transporting property and a substance having an electron accepting property has high carrier density and an excellent hole injecting property. When the layer which contains a substance having a high hole transporting property and a substance having an electron accepting property is used as a hole injecting layer which is in contact with an electrode that functions as an anode, any of various kinds of metals, alloys, electrically conductive compounds, mixtures thereof, and the like can be used regardless of the magnitude of work function of an electrode material which functions as an anode.

The layer which contains a substance having a high hole transporting property and a substance having an electron accepting property can be formed using, for example, a stack of a layer which contains a substance having a high hole transporting property and a layer which contains a substance having an electron accepting property as an evaporation source.

Examples of the substance having an electron accepting property, which is used for the hole injecting layer, include: 7,7,8,8-tetracyano-2,3,5,6-tetrafluoroquinodimethane (abbr.: F₄-TCNQ); chloranil; and the like. Other examples are transition metal oxides. Still other examples are oxides of metals belonging to Groups 4 to 8 of the periodic table. Specifically, vanadium oxide, niobium oxide, tantalum oxide, chromium oxide, molybdenum oxide, tungsten oxide, manganese oxide, and rhenium oxide are preferable because of their high electron-accepting properties. Among them, molybdenum oxide is especially preferable because it is stable also in the atmosphere, has a lows hygroscopic property, and can be easily handled.

As the substance having a high hole transporting property used for the hole injecting layer, any of various compounds such as aromatic amine compounds, carbazole derivatives, aromatic hydrocarbons, and high molecular compounds (such as oligomers, dendrimers, and polymers) can be used. Note that it is preferable that the substance having a high hole transporting property used for the hole injecting layer be a substance having a hole mobility of 10⁻⁶ cm²/Vs or higher. Note that any other substance that has a hole transporting property which is higher than an electron transporting property may be used. Specific examples of the substance having a high hole transporting property, which can be used for the hole injecting layer, are given below.

Examples of aromatic amine compounds that can be used for the hole injecting layer include: 4,4′-bis[N-(1-naphthyl)-N-phenylamino]biphenyl (abbr.: NPB); N,N′-bis(3-methylphenyl)-N,N′-diphenyl-[1,1′-biphenyl]-4,4′-diamine (abbr.: TPD); 4,4′,4″-tris(N,N-diphenylamino)triphenylamine (abbr.: TDATA); 4,4′,4″-tris[N-(3-methylphenyl)-N-phenylamino]triphenylamine (abbr.: MTDATA); 4,4′-bis[N-(spiro-9,9′-bifluoren-2-yl)-N-phenylamino]biphenyl (abbr.: BSPB); and the like. Other examples are as follows: N,N-bis(4-methylphenyl)(p-tolyl)-N,N′-diphenyl-p-phenylenediamine (abbr.: DTDPPA); 4,4′-bis[N-(4-diphenylaminophenyl)-N-phenylamino]biphenyl (abbr.: DPAB); 4,4′-bis(N-{4-[N′-(3-methylphenyl)-N′-phenylamino]phenyl}-N-phenylamino)biphenyl (abbr.: DNTPD); 1,3,5-tris[N-(4-diphenylaminophenyl)-N-phenylamino]benzene (abbr.: DPA3B); and the like.

Specific examples of carbazole derivatives that can be used for the hole injecting layer include: 3-[N-(9-phenylcarbazol-3-yl)-N-phenylamino]-9-phenylcarbazole (abbr.: PCzPCA1); 3,6-bis[N-(9-phenylcarbazol-3-yl)-N-phenylamino]-9-phenylcarbazole (abbr.: PCzPCA2); 3-[N-(1-naphthyl)-N-(9-phenylcarbazol-3-yl)amino]-9-phenylcarbazole (abbr.: PCZPCN1); and the like.

Other examples of carbazole derivatives that can be used for the hole injecting layer include: 4,4′-di(N-carbazolyl)biphenyl (abbr.: CBP); 1,3,5-tris[4-(N-carbazolyl)phenyl]benzene (abbr.: TCPB); 9-[4-(10-phenyl-9-anthryl)phenyl]-9H-carbazole (abbr.: CzPA); 1,4-bis[4-(N-carbazolyl)phenyl]-2,3,5,6-tetraphenylbenzene; and the like.

Examples of aromatic hydrocarbons that can be used for the hole injecting layer include: 2-tert-butyl-9,10-di(2-naphthyl)anthracene (abbr.: t-BuDNA); 2-tert-butyl-9,10-di(1-naphthyl)anthracene; 9,10-bis(3,5-diphenylphenyl)anthracene (abbr.: DPPA); 2-tert-butyl-9,10-bis(4-phenylphenyl)anthracene (abbr.: t-BuDBA); 9,10-di(2-naphthyl)anthracene (abbr.: DNA); 9,10-diphenylanthracene (abbr.: DPAnth); 2-tert-butylanthracene (abbr.: t-BuAnth); 9,10-bis(4-methyl-1-naphthyl)anthracene (abbr.: DMNA); 9,10-bis[2-(1-naphthyl)phenyl]-2-tert-butyl-anthracene; 9,10-bis[2-(1-naphthyl)phenyl]anthracene; 2,3,6,7-tetramethyl-9,10-di(1-naphthyl)anthracene; 2,3,6,7-tetramethyl-9,10-di(2-naphthyl)anthracene; 9,9′-bianthryl; 10,10′-diphenyl-9,9′-bianthryl; 10,10′-bis(2-phenylphenyl)-9,9′-bianthryl; 10,10′-bis[(2,3,4,5,6-pentaphenyl)phenyl]-9,9′-bianthryl; anthracene; tetracene; rubrene; perylene; 2,5,8,11-tetra(tert-butyl)perylene; and the like. Besides, pentacene, coronene, or the like can also be used. As these aromatic hydrocarbons listed here, it is preferable that an aromatic hydrocarbon having a hole mobility of 1×10⁻⁶ cm²/Vs or more and having 14 to 42 carbon atoms be used.

Note that an aromatic hydrocarbon that can be used for the hole injecting layer may have a vinyl skeleton. Examples of aromatic hydrocarbons having a vinyl group include: 4,4′-bis(2,2-diphenylvinyl)biphenyl (abbr.: DPVBi); 9,10-bis[4-(2,2-diphenylvinyl)phenyl]anthracene (abbr.: DPVPA); and the like.

The hole injecting layer can be formed by using an evaporation source in which the layer which contains a substance having a high hole transporting property and the layer which contains a substance having an electron accepting property are stacked. When a metal oxide is used as the substance having an electron accepting property, it is preferable that a layer which contains a metal oxide be formed after the layer which contains a substance having a high hole transporting property be formed over a first substrate. This is because, in many cases, a metal oxide has a higher decomposition temperature or an evaporation temperature than a substance having a high hole transporting property. The evaporation source with such a structure makes it possible to efficiently sublime a substance having a high hole transporting property and a metal oxide. In addition, local non-uniformity of the concentration in a film formed by evaporation can be suppressed. Moreover, there are few kinds of solvents which allow both a substance having a high hole transporting property and a metal oxide to be dissolved or dispersed therein, and a mixed solution is not easily formed. Therefore, it is difficult to directly form a mixed layer by a wet process. However, the use of the deposition method of the present invention makes it possible to easily form a mixed layer which contains a substance having a high hole transporting property and a metal oxide.

In addition, the layer which contains a substance having a high hole transporting property and a substance having an electron accepting property is excellent in not only a hole injecting property but also a hole transporting property, and thus the above-described hole injecting layer may be used as the hole transporting layer.

The hole transporting layer 324 is a layer which contains a substance having a high hole transporting property. Examples of the substance having a high hole transporting property include aromatic amine compounds such as 4,4′-bis[N-(1-naphthyl)-N-phenylamnino]biphenyl (abbr.: NPB or α-NPD), N,N′-bis(3-methylphenyl)-N,N′-diphenyl-[1,1′-biphenyl]-4,4′-diamine (abbr.: TPD), 4,4′,4″-tris(N,N-diphenylamino)triphenylamine (abbr.: TDATA), 4,4′,4″-tris[N-(3-methylphenyl)-N-phenylamino]triphenylamine (abbr.: MTDATA), and 4,4′-bis[N-(spiro-9,9′-bifluoren-2-yl)-N-phenylamtino]biphenyl (abbr.: BSPB), and the like. The substances listed here mainly have a hole mobility of 1×10⁻⁶ cm²/Vs or more. Note that any other material that has a hole transporting property which is higher than an electron transporting property may be used. The layer which contains a substance having a high hole transporting property is not limited to a single layer and may be a stacked layer of two or more layers formed of the above-mentioned substances.

The electron transporting layer 326 is a layer which contains a substance having a high electron transporting property. Examples of the substance having a high electron transporting property include metal complexes having a quinoline skeleton or a benzoquinoline skeleton, such as tris(8-quinolinolato)aluminum (abbr.: Alq), tris(4-methyl-8-quinolinolato)aluminum (abbr.: Almq₃), bis(10-hydroxybenzo[h]quinolinato)beryllium (abbr.: BeBq₂), and bis(2-methyl-8-quinolinolato)(4-phenylphenolato)aluminum (abbr.: BAlq), and the like. Other examples are metal complexes having an oxazole-based ligand or a thiazole-based ligand, such as bis[2-(2-hydroxyphenyl)benzoxazolato]zinc (abbr.: Zn(BOX)₂) and bis[2-(2-hydroxyphenyl)benzothiazolato]zinc (abbr.: Zn(BTZ)₂), and the like. Besides metal complexes, other examples are as follows: 2-(4-biphenylyl)-5-(4-tert-butylphenyl)-1,3,4-oxadiazole (abbr.: PBD); 1,3-bis[5-(p-tert-butylphenyl)-1,3,4-oxadiazol-2-yl]benzene (abbr.: OXD-7); 3-(4-biphenylyl)-4-phenyl-5-(4-tert-biphenyl)-1,2,4-triazole (abbr.: TAZ01); bathophenanthroline (abbr.: BPhen); bathocuproine (abbr.: BCP); and the like. The substances listed here mainly have an electron mobility of 1×10⁻⁶ cm²/Vs or higher. Note that any other material that has an electron transporting property which is higher than a hole transporting property may be used for the electron transporting layer. The electron transporting layer is not limited to a single layer and may be a stacked layer of two or more layers formed of the above-mentioned substances.

The electron injecting layer 328 can be formed using an alkali metal compound or an alkaline earth metal compound, such as lithium fluoride (LiF), cesium fluoride (CsF), or calcium fluoride (CaF₂). Furthermore, a layer, in which a substance having an electron transporting property is combined with an alkali metal or an alkaline earth metal, can be employed. For example, a layer of Alq containing magnesium (Mg) can be used. Note that it is preferable that the layer, in which a substance having an electron transporting property is combined with an alkali metal or an alkaline earth metal, be used as the electron injecting layer because electrons are efficiently injected from the second electrode layer 306.

Note that there is no particular limitation on a stack structure of layers of the EL layer 308. The EL layer 308 may be formed by an appropriate combination of a light emitting layer with any of layers which contain a substance having a high electron transporting property, a substance having a high hole transporting property, a substance having a high electron injecting property, a substance having a high hole injecting property, a bipolar substance (a substance having high electron and hole transporting properties), and the like.

Light emission is extracted to the outside through one or both of the first electrode layer 302 and the second electrode layer 306. Therefore, one or both of the first electrode layer 302 and the second electrode layer 306 is/are an electrode having a light transmitting property. In the case where only the first electrode layer 302 is an electrode having a light transmitting property, light is extracted from the substrate 300 side through the first electrode layer 302. In the case where only the second electrode layer 306 is an electrode having a light transmitting property, light is extracted from the side opposite to the substrate 300 side through the second electrode layer 306. In the case where both the first electrode layer 302 and the second electrode layer 306 are electrodes having light transmitting properties, light is extracted from both the substrate 300 side and the side opposite to the substrate 300 side through the first electrode layer 302 and the second electrode layer 306.

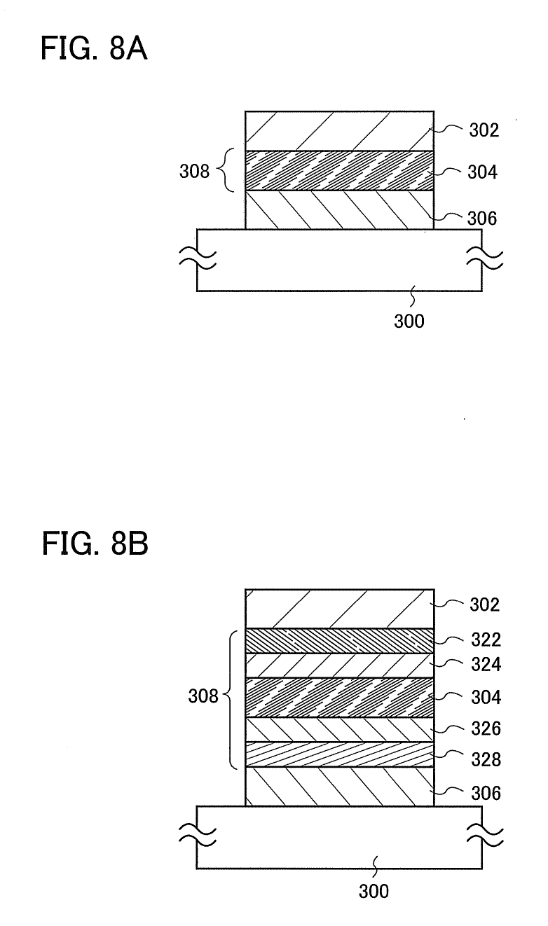

Note that, although FIGS. 7A and 7B each show the structure in which the first electrode layer 302 functioning as an anode is provided on the substrate 300 side, the second electrode layer 306 functioning as a cathode may be provided on the substrate 300 side. FIGS. 8A and 8B each show a structure in which the second electrode layer 306 functioning as a cathode, the EL layer 308, and the first electrode layer 302 functioning as an anode are stacked in order over the substrate 300. In the EL layer 308 shown in FIG. 8B, layers are stacked in the order opposite to that of the EL layer 308 shown in FIG. 7B.

The EL layer is formed by the deposition method described in Embodiment Modes 1 to 3 or may be formed by a combination of the deposition method described in Embodiment Modes 1 to 3 with another deposition method. The electrodes and the layers may each be formed using a different method. Examples of a dry process include a vacuum evaporation method, an electron beam evaporation method, a sputtering method, and the like. Examples of a wet process include an inkjet method, a spin coating method, and the like.

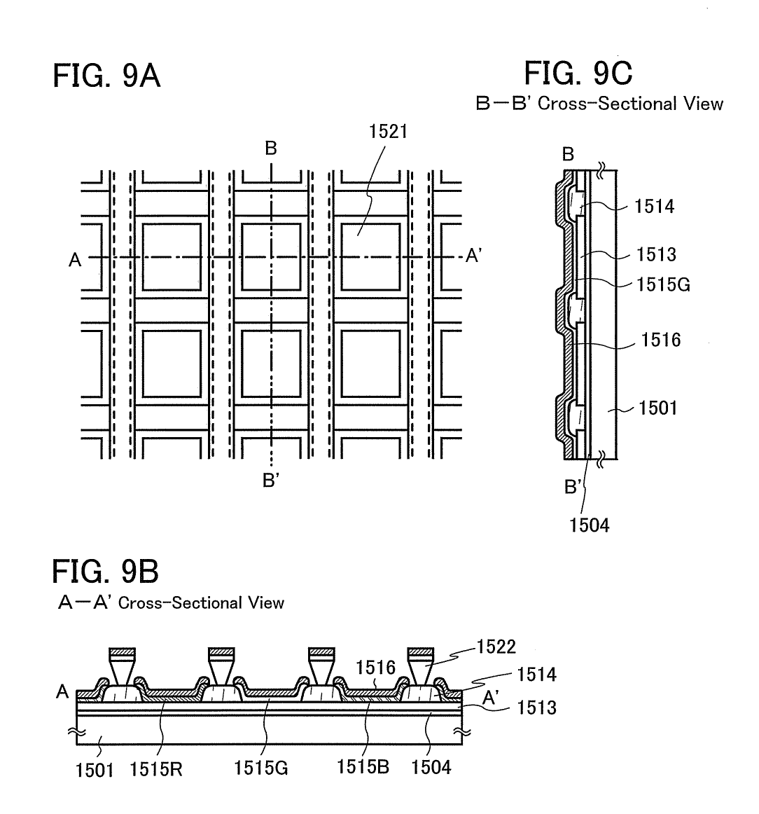

Through the above-described steps, the light emitting element can be manufactured. As for the light emitting element of this embodiment mode, layers with a variety of functions, including the light emitting layer, can be formed easily by application of the present invention. Then, a light emitting device can be manufactured by application of such a light emitting element. An example of a passive-matrix light emitting device manufactured by application of the present invention is described with reference to FIGS. 9A to 9C, FIG. 10, and FIG. 11.

In a passive-matrix (also called simple-matrix) light emitting device, a plurality of anodes arranged in stripes (in strip form) is provided to be perpendicular to a plurality of cathodes arranged in stripes. A light emitting layer is interposed at each intersection. Therefore, a pixel at an intersection of an anode selected (to which a voltage is applied) and a cathode selected emits light.

FIG. 9A shows a top view of a pixel portion before sealing. FIG. 9B shows a cross-sectional view taken along a chain line A-A′ in FIG. 9A. FIG. 9C shows a cross-sectional view taken along a dashed line B-B′.

Over a substrate 1501, an insulating layer 1504 is formed as a base insulating layer. Note that the insulating layer 1504 does not necessarily need to be formed if a base insulating layer is not necessary. A plurality of first electrode layers 1513 is arranged in stripes at regular intervals over the insulating layer 1504. A partition 1514 having openings each corresponding to a pixel is provided over the first electrode layers 1513. The partition 1514 having openings is formed using an insulating material (a photosensitive or nonphotosensitive organic material (polyimide, acrylic, polyamide, polyimide amide, or benzocyclobutene) or an SOG film (such as a SiOₓ film including an alkyl group)). Note that each opening corresponding to a pixel is a light emitting region 1521.

Over the partition 1514 having openings, a plurality of inversely tapered partitions 1522 parallel to each other is provided to intersect with the first electrode layers 1513. The inversely tapered partitions 1522 are formed by a photolithography method using a positive-type photosensitive resin, of which portion unexposed to light remains as a pattern, and by adjusting the amount of light exposure or the length of development time so that a lower portion of a pattern is etched more.

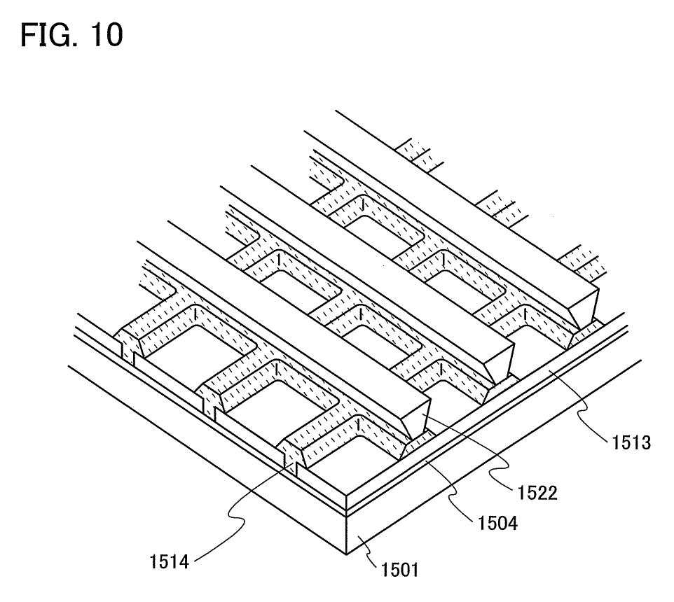

FIG. 10 shows a perspective view immediately after formation of the plurality of inversely tapered partitions 1522 parallel to each other. Note that the same reference numerals are used to denote the same portions as those in FIGS. 9A to 9C.

The total thickness of the partition 1514 having openings and each of the inversely tapered partitions 1522 is set to be larger than the total thickness of an EL layer including a light emitting layer and a conductive layer serving as a second electrode layer. When an EL layer including a light emitting layer and a conductive layer are stacked over the substrate having the structure shown in FIG. 10, they are separated into a plurality of regions, so that EL layers 1515R, 1515C, and 1515B each including a light emitting layer, and second electrode layers 1516 are formed as shown in FIGS. 9A to 9C. Note that the plurality of separated regions are electrically isolated from each other. The second electrode layers 1516 are electrodes in stripes which are parallel to each other and extended along a direction intersecting with the first electrode layers 1513. Note that EL layers each including a light emitting layer and conductive layers are also formed over the inversely tapered partitions 1522; however, they are separated from the EL layers 1515R, 1515G, and 1515B each including a light emitting layer and the second electrode layers 1516. Note that the EL layer in this embodiment mode is a layer including at least a light emitting layer and may include a hole injecting layer, a hole transporting layer, an electron transporting layer, an electron injecting layer, or the like in addition to the light emitting layer.

In this embodiment mode, an example is described in which the EL layers 1515R, 1515G, and 1515B each including a light emitting layer are selectively formed to form a light emitting device which provides three kinds of light emission (R, G, B) and is capable of full color display. The EL layers 1515R, 1515G, and 1515B each including a light emitting layer are formed in a pattern of stripes parallel to each other. These EL layers may be formed by the deposition method described in Embodiment Modes 1 to 3. For example, a first supporting substrate provided with an evaporation source for a light emitting layer providing red light emission, a second supporting substrate provided with an evaporation source for a light emitting layer providing green light emission, and a third supporting substrate provided with an evaporation source for a light emitting layer providing blue light emission are separately prepared. In addition, a substrate provided with the first electrode layers 1513 is prepared as a deposition target substrate. Then, one of the first to third supporting substrates is appropriately disposed to face the deposition target substrate, and the evaporation source formed over the supporting substrate is heated and sublimed, thereby forming EL layers including a light emitting layer over the deposition target substrate. Note that a mask or the like is appropriately used to selectively form EL layers in a desired position.

Furthermore, if necessary, sealing is performed using a sealant such as a sealant can or a glass substrate for sealing. In this embodiment mode, a glass substrate is used as a sealing substrate, and a substrate and the sealing substrate are attached to each other with an adhesive material such as a sealing material to seal a space surrounded by the adhesive material such as a sealing material. The space that is sealed is filled with a filler or a dry inert gas. In addition, a desiccant or the like may be put between the substrate and the sealing material so that reliability of the light emitting device is increased. Moisture is removed by the desiccant, whereby sufficient drying is performed. The desiccant may be a substance which absorbs moisture by chemical adsorption such as an oxide of an alkaline earth metal as typified by calcium oxide or barium oxide. A substance which adsorbs moisture by physical adsorption such as zeolite or silica gel may alternatively be used.

Note that, if the sealant is provided covering and in contact with the light emitting element to sufficiently block the outside air, the desiccant is not necessarily provided.

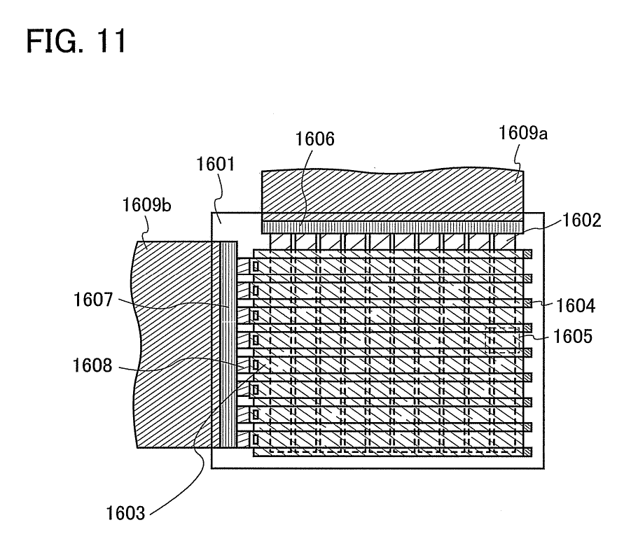

FIG. 11 shows a top view of a light emitting module mounted with an FPC or the like. In FIG. 11, a pixel portion is formed over a substrate 1601.

Note that the light emitting device in this specification refers to an image display device, a light emitting device, or a light source (including a lighting device). Furthermore, the light emitting device includes any of the following modules in its category: a module in which a connector such as a flexible printed circuit (FPC), a tape automated bonding (TAB) tape, or a tape carrier package (TCP) is attached to a light emitting device; a module having a TAB tape or a TCP provided with a printed wiring board at the end thereof; and a module having an integrated circuit (IC) directly mounted by a chip-on-glass (COG) method on a substrate provided with a light emitting element.

In the pixel portion for displaying images, scan lines and data lines intersect with each other perpendicularly as shown in FIG. 11.

The first electrode layers 1513 in FIGS. 9A to 9C correspond to scan lines 1603 in FIG. 11; the second electrode layers 1516 correspond to data lines 1602; and the inversely tapered partitions 1522 correspond to partitions 1604. EL layers each including a light emitting layer are sandwiched between the data lines 1602 and the scan lines 1603, and an intersection portion indicated by a region 1605 corresponds to one pixel.

Note that the scan lines 1603 are electrically connected at their ends to connection wirings 1608, and the connection wirings 1608 are connected to an FPC 1609b through an input terminal 1607. The data lines 1602 are connected to an FPC 1609a through an input terminal 1606.

If necessary, a polarizing plate, a circularly polarizing plate (including an elliptically polarizing plate), a retardation plate (a quarter-wave plate or a half-wave plate), or an optical film such as a color filter may be appropriately provided over a light emitting surface. Further, the polarizing plate or the circularly polarizing plate may be provided with an anti-reflection film. For example, anti-glare treatment may be carried out by which reflected light can be diffused by projections and depressions on the surface so as to reduce the glare.

In the above-described manner, a passive-matrix light emitting device can be manufactured. Application of the present invention makes it easy to form a layer containing an evaporation material forming a light emitting element and to manufacture a light emitting device including the light emitting element. In addition, less complicated control is needed in the case where a light emitting layer in which a dopant material is dispersed in a host material is formed than in the case where co-evaporation is applied. Moreover, because the additive amount of a dopant material, or the like can be easily controlled, deposition can be performed easily and precisely, and therefore a desired emission color can also be obtained easily. Furthermore, use efficiency of an evaporation material can be increased; thus, cost can be reduced.

Application of the present invention also makes it possible to form a flat film without unevenness. Application of the present invention facilitates patterning of a light emitting layer; thus, it also facilitates manufacture of a light emitting device. In addition, a precise pattern can be formed; thus, a high definition light emitting device can be obtained. Furthermore, by application of the present invention, not only a laser but also a lamp heater or the like which is inexpensive but provides a large amount of heat can be used as a light source. Accordingly, manufacturing cost of a light emitting device can be reduced.

Although FIG. 11 shows the example in which a driver circuit is not provided over the substrate, the present invention is not particularly limited to this example and an IC chip including a driver circuit may be mounted on the substrate.

In the case where an IC chip is mounted, a data line side IC and a scan line side IC, in each of which a driver circuit for transmitting a signal to the pixel portion is formed, are mounted on the periphery of (outside of) the pixel portion by a COG method. The mounting may be performed using TCP or a wire bonding method other than the COG method. TCP is a TAB tape mounted with an IC, and the TAB tape is connected to a wiring over an element-forming substrate, thereby mounting the IC. Each of the data line side IC and the scan line side IC may be formed using a silicon substrate. Alternatively, it may be that in which a driver circuit is formed using TFTs over a glass substrate, a quartz substrate, or a plastic substrate. Although described here is an example in which a single IC is provided on one side, a plurality of ICs may be provided on one side.

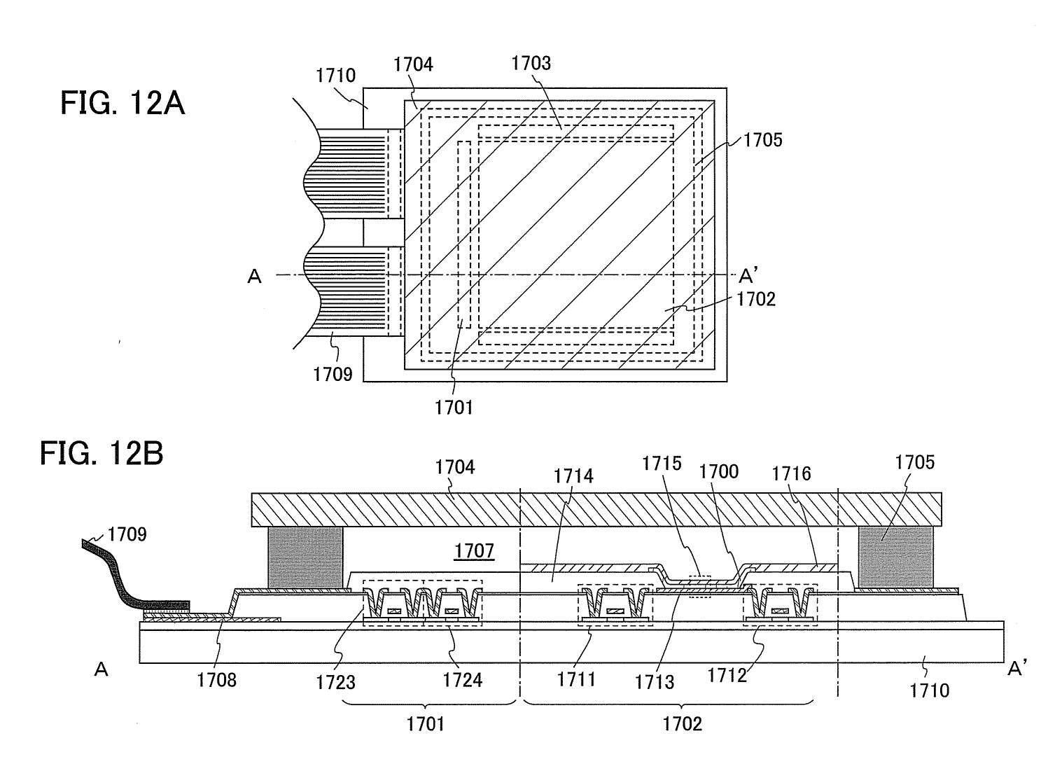

Next, an example of an active-matrix light emitting device which is manufactured by application of the present invention is described with reference to FIGS. 12A and 12B. Note that FIG. 12A is a top view showing a light emitting device and FIG. 12B is a cross-sectional view taken along a chain line A-A′ in FIG. 12A. The active-matrix light emitting device of this embodiment mode includes a pixel portion 1702 provided over an element substrate 1710, a driver circuit portion (a source-side driver circuit) 1701, and a driver circuit portion (a gate-side driver circuit) 1703. The pixel portion 1702, the driver circuit portion 1701, and the driver circuit portion 1703 are sealed, with a sealant 1705, between the element substrate 1710 and a sealing substrate 1704.

In addition, over the element substrate 1710, a lead wiring 1708 for connecting an external input terminal, through which a signal (e.g., a video signal, a clock signal, a start signal, a reset signal, or the like) or an electric potential is transmitted to the driver circuit portion 1701 and the driver circuit portion 1703, is provided. In this embodiment mode, an example is described in which a flexible printed circuit (FPC) 1709 is provided as the external input terminal. Note that only the FPC is shown here; however, the FPC may be provided with a printed wiring board (PWB). The light emitting device in this specification includes not only the main body of the light emitting device, but also the light emitting device with an FPC or a PWB attached thereto.

Next, a cross-sectional structure is described with reference to FIG. 12B. The driver circuit portions and the pixel portion are formed over the element substrate 1710; however, the pixel portion 1702 and the driver circuit portion 1701 which is the source-side driver circuit are shown.

An example is shown in which a CMOS circuit which is a combination of an n-channel TFT 1723 and a p-channel TFT 1724 is formed as the driver circuit portion 1701. Note that a circuit included in the driver circuit portion may be formed using various CMOS circuits, PMOS circuits, or NMOS circuits. In this embodiment mode, a driver-integrated type in which a driver circuit is formed over the same substrate as the pixel portion is shown; however, it is not necessarily required to have the structure, and a driver circuit can be formed not on but outside the substrate.

The pixel portion 1702 includes a plurality of pixels, each of which includes a switching TFT 1711, a current-controlling TFT 1712, and a first electrode layer 1713 which is electrically connected to a wiring (a source electrode or a drain electrode) of the current-controlling TFT 1712. Note that an insulator 1714 is formed covering an end portion of the first electrode layer 1713. In this embodiment mode, the insulator 1714 is formed using a positive photosensitive acrylic resin.

The insulator 1714 is preferably formed so as to have a curved surface with curvature at an upper end portion or a lower end portion thereof in order to obtain favorable coverage by a film which is to be stacked over the insulator 1714. For example, in the case of using a positive photosensitive acrylic resin as a material for the insulator 1714, the insulator 1714 is preferably formed so as to have a curved surface with a curvature radius (0.2 μm to 3 μm) at the upper end portion thereof. Either a negative photosensitive material which becomes insoluble in an etchant by light irradiation or a positive photosensitive material which becomes soluble in an etchant by light irradiation can be used for the insulator 1714. As the insulator 1714, without limitation to an organic compound, either an organic compound or an inorganic compound such as silicon oxide or silicon oxynitride can be used.

An EL layer 1700 including a light emitting layer and a second electrode layer 1716 are stacked over the first electrode layer 1713. The first electrode layer 1713 corresponds to the above-described first electrode layer 302, and the second electrode layer 1716 corresponds to the above-described second electrode layer 306. Note that when an ITO film is used as the first electrode layer 1713, and a stacked film of a titanium nitride film and a film containing aluminum as its main component or a stacked film of a titanium nitride film, a film containing aluminum as its main component, and a titanium nitride film is used as the wiring of the current-controlling TFT 1712 which is connected to the first electrode layer 1713, resistance of the wiring is low and favorable ohmic contact with the ITO film can be obtained. Note that, although not shown in FIGS. 12A and 12B, the second electrode layer 1716 is electrically connected to the FPC 1709 which is an external input terminal.

In the EL layer 1700, at least the light emitting layer is provided, and in addition to the light emitting layer, a hole injecting layer, a hole transporting layer, an electron transporting layer, or an electron injecting layer is provided as appropriate. The first electrode layer 1713, the EL layer 1700, and the second electrode layer 1716 are stacked, whereby a light emitting element 1715 is formed.

Although the cross-sectional view of FIG. 12B shows only one light emitting element 1715, a plurality of light emitting elements is arranged in matrix in the pixel portion 1702. Light emitting elements which provide three kinds of light emissions (R, G, and B) are selectively formed in the pixel portion 1702, whereby a light emitting device capable of full color display can be formed. Alternatively, by a combination with color filters, a light emitting device capable of full color display may be formed.

Furthermore, the sealing substrate 1704 and the element substrate 1710 are attached to each other with the sealant 1705, whereby the light emitting element 1715 is provided in a space 1707 surrounded by the element substrate 1710, the sealing substrate 1704, and the sealant 1705. Note that the space 1707 may be filled with the sealant 1705 or with an inert gas (such as nitrogen or argon).

Note that an epoxy-based resin is preferably used as the sealant 1705. It is preferable that such a material transmit as little moisture and oxygen as possible. As the sealing substrate 1704, a plastic substrate formed of fiberglass-reinforced plastics (FRP), polyvinyl fluoride (PVF), polyester, acrylic, or the like can be used besides a glass substrate or a quartz substrate.

As described above, the light emitting device can be obtained by application of the present invention. An active-matrix light emitting device tends to require high manufacturing cost per device because TFTs are manufactured; however, application of the present invention makes it possible to drastically reduce loss of materials in forming light emitting elements. Thus, cost can be reduced.

Application of the present invention makes it easy to form a layer containing an evaporation material for forming a light emitting element and to manufacture a light emitting device including the light emitting element. Application of the present invention also makes it possible to form a flat film without unevenness. Application of the present invention facilitates patterning of a light emitting layer; thus, it also facilitates manufacture of a light emitting device. In addition, a precise pattern can be formed; thus, a high definition light emitting device can be obtained. Furthermore, by application of the present invention, not only a laser but also a lamp heater or the like which is inexpensive but provides a large amount of heat can be used as a light source. Accordingly, manufacturing cost of a light emitting device can be reduced.

Note that this embodiment mode can be appropriately combined with any of the other embodiment modes described in this specification.

### Embodiment Mode 5

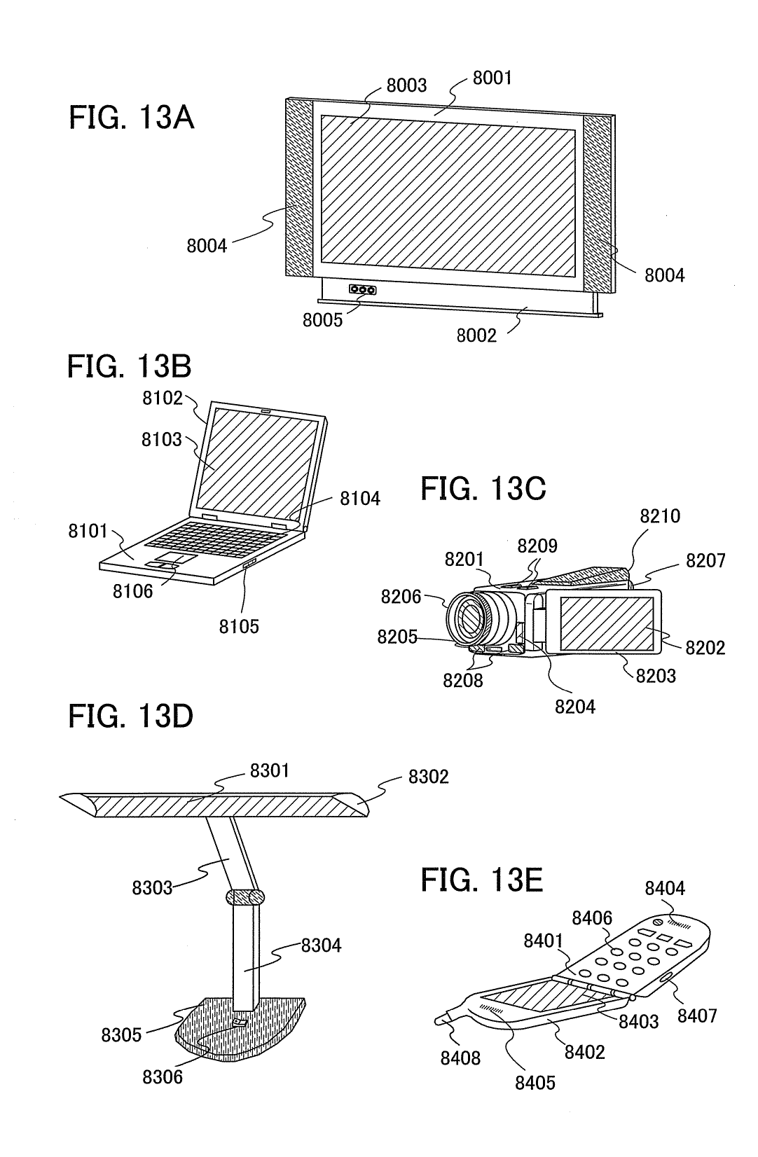

In this embodiment mode, various electronic devices each of which is completed using the light emitting device manufactured by application of the present invention are described with reference to FIGS. 13A to 13E.

Examples of electronic devices manufactured using the light emitting device of the present invention include a television, a camera such as a video camera or a digital camera, a goggle type display (head mounted display), a navigation system, an audio reproducing device (such as a car audio and an audio component), a notebook computer, a game machine, a portable information terminal (such as a mobile computer, a cellular phone, a portable game machine, and an electronic book), an image reproducing device provided with a recording medium (specifically, a device for reproducing a recording medium such as a digital video disc (DVD) and having a display device for displaying the reproduced image), a lighting device, and the like. Specific examples of these electronic devices are shown in FIGS. 13A to 13E.

FIG. 13A shows a display device, which includes a chassis 8001, a support 8002, a display portion 8003, a speaker portion 8004, a video input terminal 8005, and the like. The display device is manufactured using a light emitting device, which is formed using the present invention, in the display portion 8003. Note that the display device includes all devices for displaying information such as for a computer, for receiving TV broadcasting, and for displaying an advertisement. Because throughput can be improved by application of the present invention, productivity in manufacturing the display device can be improved. In addition, because loss of materials in manufacturing the display device can be reduced, manufacturing cost can be reduced and an inexpensive display device can be provided.

FIG. 13B shows a computer, which includes a main body 8101, a chassis 8102, a display portion 8103, a keyboard 8104, an external connecting port 8105, a pointing device 8106, and the like. The computer is manufactured using a light emitting device, which is formed using the present invention, in the display portion 8103. Because throughput can be improved by application of the present invention, productivity in manufacturing the display device can be improved. In addition, because loss of materials in manufacturing the display device can be reduced, manufacturing cost can be reduced and an inexpensive computer can be provided.

FIG. 13C shows a video camera, which includes a main body 8201, a display portion 8202, a chassis 8203, an external connecting port 8204, a remote control receiving portion 8205, an image receiving portion 8206, a battery 8207, an audio input portion 8208, an operation key 8209, an eye piece portion 8210, and the like. The video camera is manufactured using a light emitting device, which is formed using the the present invention, in the display portion 8202. Because throughput can be improved by application of the present invention, productivity in manufacturing the display device can be improved. In addition, because loss of materials in manufacturing the display device can be reduced, manufacturing cost can be reduced and an inexpensive video camera can be provided.

FIG. 13D shows a desk lamp, which includes a lighting portion 8301, a shade 8302, an adjustable arm 8303, a support 8304, a base 8305, and a power supply switch 8306. The desk lamp is manufactured using a light emitting device, which is formed using the present invention, in the lighting portion 8301. Note that a lamp includes a ceiling light, a wall light, and the like in its category. Because throughput can be improved by application of the present invention, productivity in manufacturing the light emitting device can be improved. In addition, because loss of materials in manufacturing the light emitting device can be reduced, manufacturing cost can be reduced and an inexpensive desk lamp can be provided.

FIG. 13E shows a cellular phone, which includes a main body 8401, a housing 8402, a display portion 8403, an audio input portion 8404, an audio output portion 8405, an operation key 8406, an external connecting port 8407, an antenna 8408, and the like. The cellular phone is manufactured using a light emitting device, which is formed using the present invention, in the display portion 8403. Because throughput can be improved by application of the present invention, productivity in manufacturing the display device can be improved. In addition, because loss of materials in manufacturing the display device can be reduced, manufacturing cost can be reduced and an inexpensive cellular phone can be provided.

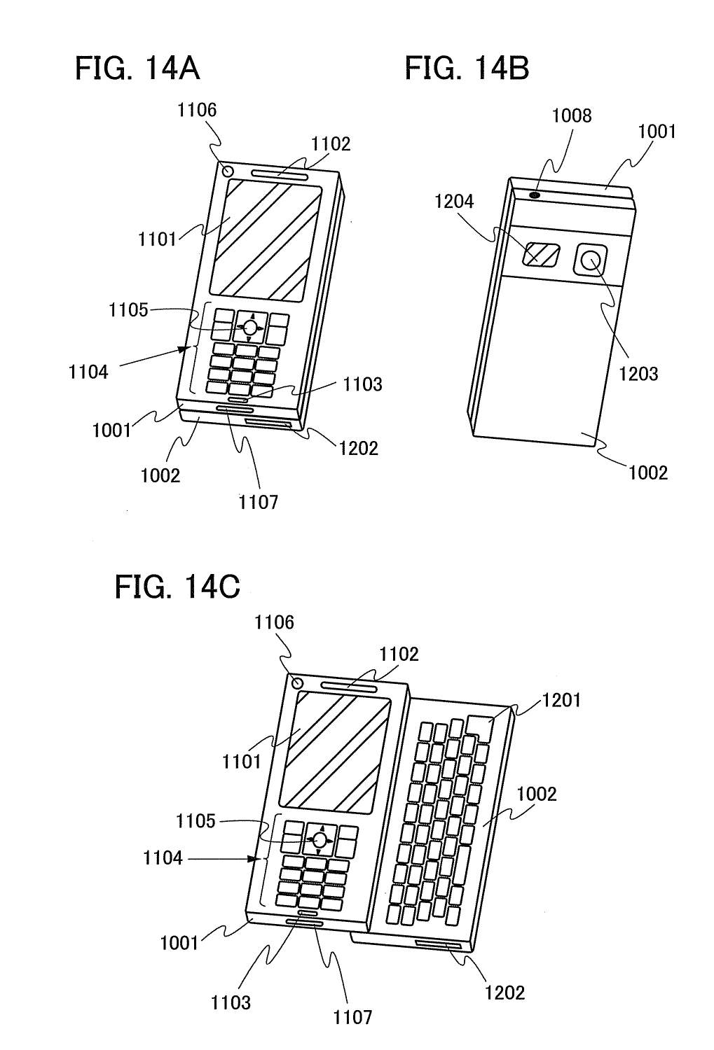

FIGS. 14A to 14C show an example of a cellular phone which has a different structure from a structure shown in FIG. 13E. FIG. 14A is a front view, FIG. 14B is a rear view, and FIG. 14C is a development view. The cellular phone in FIGS. 14A to 14C is a so-called smartphone which has both functions of a cellular phone and a portable information terminal; incorporates a computer, and conducts a variety of data processing in addition to voice calls.

The smartphone shown in FIGS. 14A to 14C has two housings 1001 and 1002. The housing 1001 includes a display portion 1101, a speaker 1102, a microphone 1103, operation keys 1104, a pointing device 1105, a camera lens 1106, an external connection terminal 1107, an earphone terminal 1108, and the like, while the housing 1002 includes a keyboard 1201, an external memory slot 1202, a camera lens 1203, a light 1204, and the like. In addition, an antenna is incorporated in the housing 1001.

Further, in addition to the above-described structure, the samrtphone may incorporate a non-contact IC chip, a small size memory device, or the like.

The light emitting device shown in Embodiment Mode 4 can be incorporated in the display portion 1101, and a display orientation can be appropriately changed according to a usage pattern. Because the camera lens 1106 is provided in the same plane as the display portion 1101, the smartphone can be used as a videophone. Further, a still image and a moving image can be taken with the camera lens 1203 and the light 1204 by using the display portion 1101 as a viewfinder. The speaker 1102 and the microphone 1103 can be used for video calling, recording and playing sound, and the like without being limited to voice calls. With the use of operation keys 1104, making and receiving calls, inputting simple information of e-mails or the like, scrolling of the screen, moving the cursor and the like are possible. Furthermore, the housing 1001 and the housing 1002 (FIG. 14A), which are overlapped with each other are slid to expose the housing 1002 as shown in FIG. 14C, and can be used as a portable information terminal. At this time, smooth operation can be conducted using the keyboard 1201 and the pointing device 1105. The external connection terminal 1107 can be connected to an AC adaptor and various types of cables such as a USB cable, and charging and data communication with a personal computer or the like are possible. Furthermore, a large amount of data can be stored and moved by inserting a recording medium into the external memory slot 1202.

In addition to the above described functions, the smartphone may have an infrared communication function, a television receiver function, and the like.

Application of the present invention makes it possible to increase throughput, and thus productivity in manufacturing the display device can be improved. In addition, loss of materials in manufacturing the display device can be reduced, and thus manufacturing costs can be reduced and inexpensive cellular phones can be provided.

In the above-described manner, electronic devices or lighting equipment can be obtained by application of the light emitting device of the present invention. The application range of the light emitting device of the present invention is so wide that the light emitting device can be applied to electronic devices in various fields.

Note that this embodiment mode can be appropriately combined with any of the other embodiment modes described in this specification.

This application is based on Japanese Patent Application serial no. 2007-274900 filed with Japan Patent Office on Oct. 23, 2007, the entire contents of which are hereby incorporated by reference.

What is claimed is:

1. A deposition method comprising the steps of:
preparing a deposition target substrate having at least a first region and a second region, wherein the first region and the second region do not overlap each other;
aligning the first region and a mask which has a smaller area than the deposition target substrate;
depositing an evaporation material on the first region;
aligning the second region of the deposition target substrate and the mask; and
depositing the evaporation material on the second region.

2. A depostion method comprising the steps of:
a first step of preparing a deposition target substrate having plural regions, wherein the plural regions do not overlap each other;
a second step of aligning one region of the plural regions and a mask which has a smaller area than the deposition target substrate;
a third step of depositing an evaporation material on one region of the plural regions;
a fourth step of aligning another region of the plural regions, on which the evaporation material is not formed, and the mask; and
a fifth step of depositing the evaporation material on another region of the plural regions,
wherein the fourth step and fifth step repeat plural times.

3. A deposition method comprising the steps of:
a first step of aligning a deposition target substrate and the mask which has smaller area than the deposition target substrate; and
a second step of vaporizing an evaporation material from a planar evaporation source, and depositing the vaporized evaporation material on at least part of the deposition target substrate,
wherein the first step and the second step repeat plural times.

4. A deposition method comprising the steps of:
a first step of aligning a deposition target substrate and a mask which has a smaller area than the deposition target substrate;
a second step of irradiating a supporting substrate with light from a light source unit, and heating the evaporation material by making irradiation light absorbed in the light absorption layer,
wherein a light absorption layer is provided over the supporting substrate, and
wherein an evaporation material is provided over the light absorption layer;
a third step of vaporizing at least part of the evaporation material, and depositing the vaporized evaporation material on at least part of a surface of the deposition target substrate through an opening of the mask; and
a fourth step of moving one of the deposition target substrate and the mask
wherein the first step through the fourth step repeat plural times.

5. The deposition method according to claim 4, wherein the light source unit is also moved when the mask is moved.

6. The deposition method according to claim 4, wherein the light emitted from the light source unit is infrared light.

7. The deposition method according to claim 4 wherein the light absorption layer has absorptance of 40% or higher with respect to the light emitted from the light source unit.

8. The deposition method according to claim 4, wherein the thickness of the light absorption layer is greater than or equal to 200 nm and less than or equal to 600 nm.

9. The deposition method according to claim 4, wherein the light absorption layer includes any one of tantalum nitride, titanium, and carbon.

10. The deposition method according to claim 4, wherein the evaporation material is formed over the supporting substrate by a wet process.

11. The deposition method according to claim 1, wherein the evaporation material is an organic compound.

12. A method for manufacturing a light emitting device, comprising the steps of:
forming a first electrode over the deposition target substrate;
forming a layer containing an evaporation material over the first electrode with the use of the deposition method described in claim 1; and
forming a second electrode over the layer.

13. The method for manufacturing a light emitting device, according to claim 12, wherein the evaporation material is one of a light emitting material and a carrier transporting material.

14. The deposition method according to claim 2, wherein the evaporation material is an organic compound.

15. A method for manufacturing a light emitting device, comprising the steps of:
forming a first electrode over the deposition target substrate;
forming a layer containing an evaporation material over the first electrode with the use of the deposition method described in claim 2; and
forming a second electrode over the layer.

16. The method for manufacturing a light emitting device, according to claim 15, wherein the evaporation material is one of a light emitting material and a carrier transporting material.

17. The deposition method according to claim 3, wherein the evaporation material is an organic compound.

18. A method for manufacturing a light emitting device, comprising the steps of:
forming a first electrode over the deposition target substrate;
forming a layer containing an evaporation material over the first electrode with the use of the deposition method described in claim 3; and
forming a second electrode over the layer.

19. The method for manufacturing a light emitting device, according to claim 18, wherein the evaporation material is one of a light emitting material and a carrier transporting material.

20. The deposition method according to claim 4, wherein the evaporation material is an organic compound.

21. A method for manufacturing a light emitting device, comprising the steps of:
forming a first electrode over the deposition target substrate;
forming a layer containing an evaporation material over the first electrode with the use of the deposition method described in claim 4; and
forming a second electrode over the layer.

22. The method for manufacturing a light emitting device, according to claim 21, wherein the evaporation material is one of a light emitting material and a carrier transporting material.
